(19) United States
(12) Patent Application Publication
(10) Pub. No.: US 2024/0213360 A1
(43) Pub. Date: Jun. 27, 2024

(54) SEMICONDUCTOR DEVICE, SEMICONDUCTOR DEVICE MANUFACTURING METHOD, AND ELECTRONIC DEVICE

(71) Applicant: Fujitsu Limited, Kawasaki-shi (JP)

(72) Inventors: Shirou OZAKI, Yamato (JP); Naoya OKAMOTO, Isehara (JP); Yusuke KUMAZAKI, Atsugi (JP); Yasuhiro NAKASHA, Hadano (JP); Naoki HARA, Sagamihara (JP); Toshihiro OHKI, Hadano (JP)

(73) Assignee: Fujitsu Limited, Kawasaki-shi (JP)

(21) Appl. No.: 18/465,784

(22) Filed: Sep. 12, 2023

(30) Foreign Application Priority Data
Dec. 26, 2022 (JP) 2022-208726

(51) Int. Cl. H01L 29/778; H01L 23/31; H01L 29/205; H01L 29/423; H01L 29/66

(52) U.S. Cl. CPC H01L 29/7786; H01L 23/3171; H01L 29/205; H01L 29/42316; H01L 29/66462; H02M 1/4208

(57) ABSTRACT

A semiconductor device has a semiconductor layer including a channel layer containing indium (In), gallium (Ga), and arsenic (As) and an electron supply layer laminated over the channel layer and containing In, Al, and As. A source electrode and a drain electrode are formed on a surface side of the semiconductor layer, and a gate electrode is formed between them. A positively charged insulating film containing aluminum oxide (AlₓO_{y}) (y/x<3/2) having oxygen vacancies is formed on the source electrode side from the gate electrode on the surface side of the semiconductor layer. A part of the insulating film may function as a gate insulating film. The density of a two dimensional electron gas (2DEG) in the channel layer on the source electrode side from the gate electrode is relatively higher than that of the 2DEG on the drain electrode side therefrom because of the insulating film.

### CROSS-REFERENCE TO RELATED APPLICATION

This application is based upon and claims the benefit of priority of the prior Japanese Patent Application No. 2022-208726, filed on Dec. 26, 2022, the entire contents of which are incorporated herein by reference.

### FIELD

The embodiments discussed herein relate to a semiconductor device, a semiconductor device manufacturing method, and an electronic device.

### BACKGROUND

A high electron mobility transistor (HEMT) formed by the use of a gallium-nitride-based nitride semiconductor is known as an example of a semiconductor device. With such a HEMT, for example, the following technique is known. A gate electrode, a source electrode, and a drain electrode are formed over a semiconductor laminated structure formed by the use of a nitride semiconductor, a positively charged insulating film is formed between the gate electrode and the source electrode and a covalent insulating film is formed between the gate electrode and the drain electrode. It is suggested that an aluminum-rich aluminum oxide or the like be used as a positively charged insulating film.

See, for example, Japanese Laid-open Patent Publication No. 2021-192410.

### SUMMARY

According to an aspect, there is provided a semiconductor device including: a semiconductor layer including a first layer containing indium, gallium, and arsenic and a second layer laminated over the first layer and containing indium, aluminum, and arsenic; a source electrode and a drain electrode provided on a first surface side of the semiconductor layer where a first surface of the semiconductor layer is located; a gate electrode provided on the first surface side of the semiconductor layer between the source electrode and the drain electrode; and a first insulating film provided on the first surface side of the semiconductor layer and on a source electrode side, where the source electrode is provided, from the gate electrode, the first insulating film containing aluminum oxide having oxygen vacancies.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a view for describing an example of a semiconductor device according to a first embodiment;

FIGS. 2A through 2C are views for describing other examples of the semiconductor device according to the first embodiment;

FIG. 3 is a view for describing a semiconductor device according to a first configuration example of a second embodiment;

FIGS. 4A and 4B are views for describing a method for manufacturing the semiconductor device according to the first configuration example of the second embodiment (part 1);

FIGS. 5A and 5B are views for describing a method for manufacturing the semiconductor device according to the first configuration example of the second embodiment (part 2);

FIGS. 6A and 6B are views for describing a method for manufacturing the semiconductor device according to the first configuration example of the second embodiment (part 3);

FIG. 7 is a view for describing a semiconductor device according to a second configuration example of the second embodiment;

FIGS. 8A and 8B are views for describing a method for manufacturing the semiconductor device according to the second configuration example of the second embodiment;

FIG. 9 is a view for describing further the method for manufacturing the semiconductor device according to the second configuration example of the second embodiment;

FIG. 10 is a view for describing further the semiconductor device according to the second configuration example of the second embodiment;

FIGS. 11A and 11B are views for describing a modification of the semiconductor device according to the second configuration example of the second embodiment;

FIG. 12 is a view for describing another modification of the semiconductor device according to the second configuration example of the second embodiment;

FIG. 13 is a view for describing a semiconductor device according to a third configuration example of the second embodiment;

FIGS. 14A and 14B are views for describing a method for manufacturing the semiconductor device according to the third configuration example of the second embodiment;

FIGS. 15A and 15B are views for describing a semiconductor device used for characteristic evaluation;

FIGS. 16A and 16B are views for describing the current-voltage characteristic of a semiconductor device (part 1);

FIGS. 17A and 17B are views for describing the current-voltage characteristic of a semiconductor device (part 2);

FIGS. 18A and 18B are views for describing the current-voltage characteristic of a semiconductor device (part 3);

FIGS. 19A and 19B are views for describing the current-voltage characteristic of a semiconductor device (part 4);

FIGS. 20A and 20B are views for describing the breakdown voltage of a semiconductor device;

FIG. 21 is a view for describing the relationship between the distance from a gate edge on a drain side to an insulating film edge in a semiconductor device and the breakdown voltage of the semiconductor device;

FIG. 22 is a view for describing a semiconductor device according to a first configuration example of a fourth embodiment;

FIG. 23 is a view for describing a semiconductor device according to a second configuration example of the fourth embodiment;

FIG. 24 is a view for describing an example of a semiconductor package according to a fifth embodiment;

FIG. 25 is a view for describing an example of a power factor correction circuit according to a sixth embodiment;

FIG. 26 is a view for describing an example of a power supply device according to a seventh embodiment; and

FIG. 27 is a view for describing an example of an amplifier according to an eighth embodiment.

### DESCRIPTION OF EMBODIMENTS

A HEMT is known as an example of a semiconductor device. With such a HEMT, a layer of a compound semiconductor containing indium, gallium, and arsenic is used as a channel layer and a layer of a compound semiconductor containing indium, aluminum, and arsenic is used as an electron supply layer. With such a HEMT, a two dimensional electron gas (2DEG) is generated in the channel layer over which the electron supply layer is laminated. If the density of a 2DEG generated in the channel layer between a source and a drain in such a HEMT using a compound semiconductor is increased as a whole to obtain a large current and a high output, then a comparatively strong electric field is generated on the drain side and the breakdown voltage may drop.

### First Embodiment

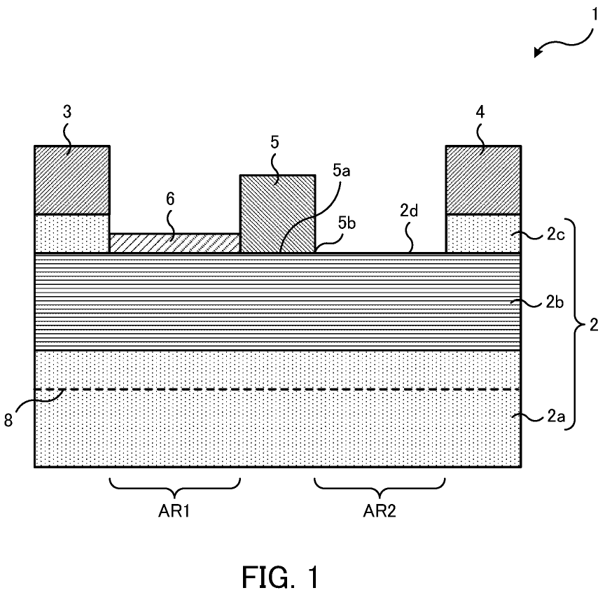

FIG. 1 is a view for describing an example of a semiconductor device according to a first embodiment. FIG. 1 is a fragmentary schematic sectional view of an example of a semiconductor device.

A semiconductor device 1 illustrated in FIG. 1 is an example of a HEMT. The semiconductor device 1 has a semiconductor layer 2, a source electrode 3, a drain electrode 4, a gate electrode 5, and an insulating film 6.

The semiconductor layer 2 includes a channel layer 2a and an electron supply layer 2b. Furthermore, the semiconductor layer 2 includes a cap layer 2c.

A compound semiconductor containing indium (In), gallium (Ga), and arsenic (As) is used for forming the channel layer 2a. For example, indium gallium arsenide (InGaAs) is used for forming the channel layer 2a. Alternatively, a compound semiconductor containing not only In, Ga, and As but also another element may be used for forming the channel layer 2a. A compound semiconductor containing at least In, Ga, and As is also referred to as an “In—Ga—As based material”. The channel layer 2a is also referred to as a carrier transit layer, an electron transit layer, or the like.

As illustrated in FIG. 1, for example, the electron supply layer 2b is laminated on one surface side of the channel layer 2a. A compound semiconductor containing In, aluminum (Al), and As is used for forming the electron supply layer 2b. For example, indium aluminum arsenide (InAlAs) is used for forming the electron supply layer 2b. Alternatively, a compound semiconductor containing not only In, Al, and As but also another element may be used for forming the electron supply layer 2b. A compound semiconductor containing at least In, Al, and As is also referred to as an “In—Al—As based material”. The electron supply layer 2b is also referred to as a carrier supply layer, a barrier layer, or the like.

As illustrated in FIG. 1, for example, the cap layer 2c is laminated on one surface side of the electron supply layer 2b. A compound semiconductor containing In, Ga, and As is used for forming the cap layer 2c. For example, InGaAs is used for forming the cap layer 2c. Alternatively, a compound semiconductor containing not only In, Ga, and As but also another element may be used for forming the cap layer 2c. An In—Ga—As based material is used for forming the cap layer 2c.

A 2DEG 8 is generated in the channel layer 2a of the semiconductor layer 2 over which the electron supply layer 2b is laminated. In the semiconductor layer 2, the density of the 2DEG 8 directly under a region in which the cap layer 2c is formed (mesa of the cap layer 2c) is higher than that of the 2DEG 8 directly under a region in which the cap layer 2c is not formed (recess in the cap layer 2c).

For example, the semiconductor layer 2 is grown over a determined substrate (not illustrated) made of indium phosphide (InP) by the use of a metal organic chemical vapor deposition (MOCVD) method or the like. The semiconductor device 1 in which the semiconductor layer 2 including the channel layer 2a formed by the use of an In—Ga—As based material and the electron supply layer 2b formed by the use of an In—Al—As based material is formed over an InP substrate is also referred to as an InP-based HEMT. In the semiconductor device 1, a substrate over which the semiconductor layer 2 is formed is not limited to an InP substrate.

The gate electrode 5, the source electrode 3, and the drain electrode 4 are formed on one surface 2d side of the semiconductor layer 2.

The source electrode 3 and the drain electrode 4 are formed over the cap layer 2c on the surface 2d side of the semiconductor layer 2. The source electrode 3 and the drain electrode 4 are formed apart from each other. The source electrode 3 and the drain electrode 4 are formed by the use of a metal material such as titanium (Ti), platinum (Pt), or gold (Au). The source electrode 3 and the drain electrode 4 are formed so as to function as an ohmic electrode. The source electrode 3 and the drain electrode 4 are formed over the cap layer 2c and the 2DEG 8 generated in the channel layer 2a directly under the cap layer 2c is relatively dense. As a result, a relatively good ohmic connection is realized.

The gate electrode 5 is formed between the source electrode 3 and the drain electrode 4 on the surface 2d side of the semiconductor layer 2, that is to say, between the cap layers 2c over which the source electrode 3 and the drain electrode 4 are formed apart from the source electrode 3 and the drain electrode 4. The gate electrode 5 is formed by the use of a metal material such as Ti, Pt, or Au. For example, the gate electrode 5 is formed on the surface 2d side of the semiconductor layer 2 so as to function as a Schottky electrode. Alternatively, the gate electrode 5 may be formed over the surface 2d of the semiconductor layer 2 with a gate insulating film (not illustrated) therebetween so as to realize a metal insulator semiconductor (MIS)-type gate structure.

At the time of the operation of the semiconductor device 1, for example, a voltage is applied such that the drain electrode 4 has a high potential with respect to the source electrode 3, and a determined voltage is applied to the gate electrode 5. By a field effect produced by the voltage applied to the gate electrode 5, the amount of electric charges of the 2DEG 8 passing directly under the gate electrode 5 between the source electrode 3 and the drain electrode 4 is controlled and the magnitude of an output drain current is controlled. With the semiconductor device 1, the channel layer 2a is formed by the use of an In—Ga—As based material and the electron supply layer 2b is formed by the use of an In—Al—As based material. Such a HEMT is excellent in high-speed operation and has a low-noise characteristic. Accordingly, such a HEMT is used in amplifiers, signal processing circuits, and the like. Such a HEMT is suitable for amplifiers used in a frequency band corresponding to a microwave or a millimeter wave, amplifiers used in a frequency band corresponding to a terahertz wave, signal processing circuits in optical communication, and the like.

As illustrated in FIG. 1, with the semiconductor device 1, for example, the insulating film 6 is formed on the surface 2d side of the semiconductor layer 2 on which the gate electrode 5, the source electrode 3, and the drain electrode 4 are formed and on the source electrode 3 side from the gate electrode 5. The insulating film 6 contains aluminum oxide having oxygen vacancies. Aluminum oxide is expressed by the composition formula AlₓO_{y}. If aluminum oxide has oxygen vacancies, then the composition ratio of O to Al, that is to say, y/x is smaller than 3/2. The insulating film 6 containing AlₓO_{y} (y/x<3/2) having oxygen vacancies is positively charged. With the semiconductor device 1, the insulating film 6 which contains AlₓO_{y} (y/x<3/2) having oxygen vacancies and which is positively charged is formed on the surface 2d side of the semiconductor layer 2 and on the source electrode 3 side from the gate electrode 5.

In the semiconductor device 1, the channel layer 2a and the electron supply layer 2b of the semiconductor layer 2 are also referred to as a “first layer” and a “second layer”, respectively. In the semiconductor device 1, the surface 2d of the semiconductor layer 2 is also referred to as a “first surface”. In the semiconductor device 1, the insulating film 6 is also referred to as a “first insulating film”.

With the semiconductor device 1, the insulating film 6 which contains AlₓO_{y} (y/x<3/2) having oxygen vacancies and which is positively charged is formed on the surface 2d side of the semiconductor layer 2 on which the gate electrode 5, the source electrode 3, and the drain electrode 4 are formed and on the source electrode 3 side from the gate electrode 5. By forming the insulating film 6 which is positively charged in the semiconductor device 1, the density of the 2DEG 8 directly under an area between the gate electrode 5 and the source electrode 3 (in an area AR1 in FIG. 1) is increased. That is to say, a conduction band of a bonding portion between the channel layer 2a and the electron supply layer 2b directly under the area between the gate electrode 5 and the source electrode 3 is pushed down due to positive fixed charges in the insulating film 6. As a result, the density of the 2DEG 8 directly under the area between the gate electrode 5 and the source electrode 3 increases.

With the semiconductor device 1, it may safely be said that because of the insulating film 6, the density of the 2DEG 8 directly under the area between the gate electrode 5 and the source electrode 3 (in the area AR1 in FIG. 1) is relatively higher than that of the 2DEG 8 directly under an area between the gate electrode 5 and the drain electrode 4 (in an area AR2 in FIG. 1). In other words, with the semiconductor device 1, it may safely be said that because of the insulating film 6, the density of the 2DEG 8 directly under the area between the gate electrode 5 and the drain electrode 4 is relatively lower than that of the 2DEG 8 directly under the area between the gate electrode 5 and the source electrode 3.

With the semiconductor device 1, the density of the 2DEG 8 directly under the area between the gate electrode 5 and the source electrode 3 increases because of the insulating film 6. As a result, the resistance of the channel layer 2a between the gate electrode 5 and the source electrode 3 lowers. Accordingly, the resistance of the channel layer 2a between the drain electrode 4 and the source electrode 3 lowers. This increases a current and an output of the semiconductor device 1.

Furthermore, with the semiconductor device 1, an increase in the density of the 2DEG 8 directly under the area between the gate electrode 5 and the drain electrode 4 is suppressed. As a result, an electric field generated in the semiconductor layer 2 between the gate electrode 5 and the drain electrode 4 is suppressed. In addition, electric field concentration at an edge 5b on the drain electrode 4 side (also referred to as a “drain-side gate edge 5b”) of an end surface 5a of the gate electrode 5 which faces the surface 2d of the semiconductor layer 2 is suppressed. This suppresses a drop in the breakdown voltage of the semiconductor device 1.

The insulating film 6 containing AlₓO_{y} (y/x<3/2) having oxygen vacancies is formed on the source electrode 3 side from the gate electrode 5 on the surface 2d side of the semiconductor layer 2 on which the gate electrode 5, the source electrode 3, and the drain electrode 4 are formed. By doing so, a high output and high breakdown voltage semiconductor device 1 is realized.

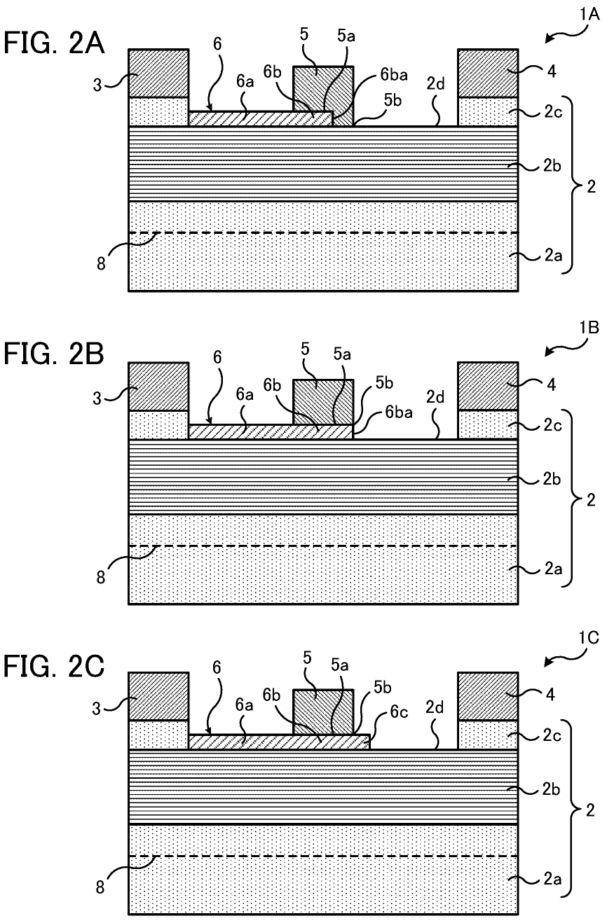

FIGS. 2A through 2C are views for describing other examples of the semiconductor device according to the first embodiment. Each of FIGS. 2A through 2C is a fragmentary schematic sectional view of an example of the semiconductor device.

With a semiconductor device 1A illustrated in FIG. 2A, an insulating film 6 including a first portion 6a and a second portion 6b is formed. The first portion 6a is formed on the source electrode 3 side from a gate electrode 5. The second portion 6b connects with the first portion 6a and is formed between a surface 2d of a semiconductor layer 2 and an end surface 5a of the gate electrode 5. An edge 6ba on the drain electrode 4 side of the second portion 6b is situated on the source electrode 3 side from a gate edge 5b on the drain electrode 4 side. With the semiconductor device 1A, the second portion 6b, which is part of the insulating film 6, extends from the source electrode 3 side to a position between the surface 2d of the semiconductor layer 2 and the end surface 5a of the gate electrode 5 and does not reach the gate edge 5b on the drain electrode 4 side.

In the semiconductor device 1A, a channel layer 2a and an electron supply layer 2b of the semiconductor layer 2 are also referred to as a “first layer” and a “second layer”, respectively. In the semiconductor device 1A, the surface 2d of the semiconductor layer 2 is also referred to as a “first surface”. In the semiconductor device 1A, the first portion 6a and the second portion 6b of the insulating film 6 are also referred to as a “first insulating film” and a “second insulating film”, respectively.

With the semiconductor device 1A, the second portion 6b of the insulating film 6 intervening between the surface 2d of the semiconductor layer 2 and the end surface 5a of the gate electrode 5 functions as a gate insulating film. As a result, with the semiconductor device 1A, generation of a gate leakage current is suppressed.

With the semiconductor device 1A, the density of a 2DEG 8 directly under the first portion 6a and the second portion 6b of the insulating film 6 increases because of the insulating film 6 containing AlₓO_{y} (y/x<3/2) having oxygen vacancies. This increases a current and an output of the semiconductor device 1A.

With the semiconductor device 1A, the density of the 2DEG 8 directly under an area between the gate electrode 5 and the drain electrode 4 is relatively lower than that of the 2DEG 8 directly under an area between the gate electrode 5 and the source electrode 3. As a result, an electric field generated in the semiconductor layer 2 between the gate electrode 5 and the drain electrode 4 is suppressed. Furthermore, with the semiconductor device 1A, the edge 6ba of the second portion 6b of the insulating film 6 does not reach the gate edge 5b on the drain electrode 4 side. As a result, even if the second portion 6b contains AlₓO_{y} (y/x<3/2) having oxygen vacancies, an increase in the density of the 2DEG 8 directly under the gate edge 5b on the drain electrode 4 side is suppressed and electric field concentration at the gate edge 5b on the drain electrode 4 side is suppressed. This suppresses a drop in the breakdown voltage of the semiconductor device 1A.

The above insulating film 6 including the first portion 6a and the second portion 6b is used and a high output and high breakdown voltage semiconductor device 1A is realized.

If the second portion 6b of the insulating film 6 in the semiconductor device 1A which functions as a gate insulating film contains AlₓO_{y} (y/x<3/2) having oxygen vacancies, then the oxygen vacancies may become electron trap sites. If the oxygen vacancies in the second portion 6b become electron trap sites, then the characteristics of the semiconductor device 1A may vary. For example, the threshold voltage may shift. In view of this, with the semiconductor device 1A, the number of oxygen vacancies in the second portion 6b which functions as a gate insulating film may be made smaller than that of oxygen vacancies in the first portion 6a formed on the source electrode 3 side from the gate electrode 5. For example, the second portion 6b, of the first portion 6a and the second portion 6b of the insulating film 6, is selectively oxidized. By doing so, the number of oxygen vacancies in the second portion 6b is made smaller than that of oxygen vacancies in the first portion 6a.

As has been described, the insulating film 6 of the semiconductor device 1A may include the first portion 6a having a relatively large number of oxygen vacancies and the second portion 6b having a relatively small number of oxygen vacancies or no oxygen vacancies. That is to say, with the semiconductor device 1A, the insulating film 6 in which the composition ratio of O to Al, or y/x, of AlₓO_{y} contained in the second portion 6b is larger than the composition ratio of O to Al, or y/x, of AlₓO_{y} contained in the first portion 6a may be formed. This suppresses variation in the characteristics of the semiconductor device 1A caused by electron traps in the second portion 6b.

Furthermore, if the second portion 6b of the insulating film 6 of the semiconductor device 1A has a relatively small number of oxygen vacancies or no oxygen vacancies, then an increase in the density of the 2DEG 8 directly under the gate edge 5b on the drain electrode 4 side is suppressed more effectively. As a result, electric field concentration at the gate edge 5b on the drain electrode 4 side is suppressed more effectively and a drop in the breakdown voltage of the semiconductor device 1A is suppressed more effectively.

Moreover, with a semiconductor device 1B illustrated in FIG. 2B, an insulating film 6 includes a first portion 6a and a second portion 6b and an edge 6ba of the second portion 6b on the drain electrode 4 side is situated at a gate edge 5b on the drain electrode 4 side.

In the semiconductor device 1B, a channel layer 2a and an electron supply layer 2b of a semiconductor layer 2 are also referred to as a “first layer” and a “second layer”, respectively. In the semiconductor device 1B, a surface 2d of the semiconductor layer 2 is also referred to as a “first surface”. In the semiconductor device 1B, the first portion 6a and the second portion 6b of the insulating film 6 are also referred to as a “first insulating film” and a “second insulating film”, respectively.

With the semiconductor device 1B illustrated in FIG. 2B, a high output and a high breakdown voltage are realized by the first portion 6a and the second portion 6b of the insulating film 6 containing AlₓO_{y} (y/x<3/2) having oxygen vacancies. This is the same with the above semiconductor device 1A.

With the semiconductor device 1B, the edge 6ba of the second portion 6b on the drain electrode 4 side is situated at the gate edge 5b on the drain electrode 4 side at which electric field concentration relatively tends to occur. Accordingly, if the number of oxygen vacancies in the second portion 6b is made smaller than that of oxygen vacancies in the first portion 6a in the semiconductor device 1B, then an increase in the density of a 2DEG 8 directly under the gate edge 5b on the drain electrode 4 side is suppressed. As a result, electric field concentration at the gate edge 5b on the drain electrode 4 side is suppressed and a drop in the breakdown voltage caused by electric field concentration is suppressed. If the number of oxygen vacancies in the second portion 6b is made smaller than that of oxygen vacancies in the first portion 6a in the semiconductor device 1B, then electron traps in the second portion 6b which functions as a gate insulating film are also suppressed.

Furthermore, with a semiconductor device 1C illustrated in FIG. 2C, an insulating film 6 includes a first portion 6a, a second portion 6b, and a third portion 6c. The first portion 6a is formed on the source electrode 3 side from a gate electrode 5. The second portion 6b connects with the first portion 6a and is formed between a surface 2d of a semiconductor layer 2 and an end surface 5a of the gate electrode 5. The third portion 6c connects with the second portion 6b and is formed on the drain electrode 4 side from the gate electrode 5. The third portion 6c extends from the gate electrode 5 to a position that does not reach a drain electrode 4 or a cap layer 2c over which the drain electrode 4 is formed.

In the semiconductor device 1C, a channel layer 2a and an electron supply layer 2b of the semiconductor layer 2 are also referred to as a “first layer” and a “second layer”, respectively. In the semiconductor device 1C, the surface 2d of the semiconductor layer 2 is also referred to as a “first surface”. In the semiconductor device 1C, the first portion 6a, the second portion 6b, and the third portion 6c of the insulating film 6 are also referred to as a “first insulating film”, a “second insulating film”, and a “third insulating film”, respectively.

With the semiconductor device 1C, the density of a 2DEG 8 directly under the first portion 6a, the second portion 6b, and the third portion 6c of the insulating film 6 increases because of the insulating film 6 including the first portion 6a, the second portion 6b, and the third portion 6c and containing AlₓO_{y} (y/x<3/2) having oxygen vacancies. This increases a current and an output of the semiconductor device 1C.

With the semiconductor device 1C, the third portion 6c of the insulating film 6 is formed on the drain electrode 4 side from the gate electrode 5. The third portion 6c extends from the gate electrode 5 to the position that does not reach the drain electrode 4 or the cap layer 2c over which the drain electrode 4 is formed. Accordingly, an increase in the density of the 2DEG 8 directly under an area between the gate electrode 5 and the drain electrode 4 is suppressed compared with a case where the insulating film 6 containing AlₓO_{y} (y/x<3/2) having oxygen vacancies is formed in the whole of the area between gate electrode 5 and the drain electrode 4. As a result, an electric field generated in the semiconductor layer 2 between the gate electrode 5 and the drain electrode 4 is suppressed and a drop in the breakdown voltage of the semiconductor device 1C is suppressed.

With the semiconductor device 1C illustrated in FIG. 2C, a high output and a high breakdown voltage are also realized by the insulating film 6 including the first portion 6a, the second portion 6b, and the third portion 6c.

If the number of oxygen vacancies in the second portion 6b intervening between the semiconductor layer 2 and the gate electrode 5 is made smaller than that of oxygen vacancies in the first portion 6a in the semiconductor device 1C, then electron traps in the second portion 6b which functions as a gate insulating film are suppressed and a drop in the breakdown voltage is suppressed. If the number of oxygen vacancies in the third portion 6c formed on the drain electrode 4 side from the gate electrode 5 is made smaller than that of oxygen vacancies in the first portion 6a in the semiconductor device 1C, then an increase in the density of the 2DEG 8 directly under the area between the gate electrode 5 and the drain electrode 4 is suppressed and a drop in the breakdown voltage is suppressed. In the semiconductor device 1C, the number of oxygen vacancies in the second portion 6b and the third portion 6c may be made smaller than that of oxygen vacancies in the first portion 6a.

With the above semiconductor device 1 (FIG. 1), semiconductor device 1A (FIG. 2A), semiconductor device 1B (FIG. 2B), and semiconductor device 1C (FIG. 2C), as the thickness of the insulating film 6 containing AlₓO_{y} (y/x<3/2) having oxygen vacancies increases, the influence of positive charges in the insulating film 6 may grow.

Accordingly, with the semiconductor device 1A (FIG. 2A) and the semiconductor device 1B (FIG. 2B), a side on the drain electrode 4 side of the second portion 6b of the insulating film 6 may be inclined such that the thickness of the insulating film 6 decreases toward the drain electrode 4 side. With the semiconductor device 1C (FIG. 2C), a side on the drain electrode 4 side of the third portion 6c of the insulating film 6 may be inclined such that the thickness of the insulating film 6 decreases toward the drain electrode 4 side. If the insulating film 6 contains AlₓO_{y} (y/x<3/2) having oxygen vacancies, then this method reduces the influence of positive charges in the insulating film 6, suppresses an increase in the density of the 2DEG 8, and suppresses a drop in the breakdown voltage, directly under the inclined side of the second portion 6b or the third portion 6c.

Furthermore, with the semiconductor device 1A (FIG. 2A), the semiconductor device 1B (FIG. 2B), and the semiconductor device 1C (FIG. 2C), the thickness of the second portion 6b of the insulating film 6 may be made smaller than that of the first portion 6a. With the semiconductor device 1C (FIG. 2C), the thickness of the third portion 6c of the insulating film 6 may be made smaller than that of the first portion 6a. If the insulating film 6 contains AlₓO_{y} (y/x<3/2) having oxygen vacancies, then this method reduces the influence of positive charges in the insulating film 6, suppresses an increase in the density of the 2DEG 8, and suppresses a drop in the breakdown voltage, directly under the second portion 6b or the third portion 6c whose thickness is reduced. If the thickness of the second portion 6b is made smaller than that of the first portion 6a, then the thickness of the first portion 6a is set to a value which is effective for an increase in the density of the 2DEG 8 and the thickness of the second portion 6b is set to a value by which it effectively functions as a gate insulating film.

In addition, with the above semiconductor device 1 (FIG. 1), semiconductor device 1A (FIG. 2A), semiconductor device 1B (FIG. 2B), and semiconductor device 1C (FIG. 2C), what is called an asymmetrical arrangement may be adopted. That is to say, the gate electrode 5 is located nearer to the source electrode 3 than to the drain electrode 4. By adopting this asymmetrical arrangement, the breakdown voltage of the semiconductor device 1, 1A, 1B, or 1C is raised further.

Furthermore, with the above semiconductor devices 1, 1A, 1B, and 1C, the semiconductor layer 2 including the channel layer 2a and the electron supply layer 2b laminated thereover is used and the gate electrode 5, the source electrode 3, the drain electrode 4, and the insulating film 6 are formed on the electron supply layer 2b side of the semiconductor layer 2. In addition, a semiconductor layer including the electron supply layer 2b and the channel layer 2a laminated thereover may be used. The gate electrode 5, the source electrode 3, the drain electrode 4, and the insulating film 6 may be formed on the channel layer 2a side of this semiconductor layer. The same effect that is described for the above semiconductor devices 1, 1A, 1B, and 1C is obtained by a semiconductor device in which such a structure is adopted.

### Second Embodiment

A configuration example of a semiconductor device will now be described as a second embodiment.

First a first configuration example of a semiconductor device according to a second embodiment will be descried.

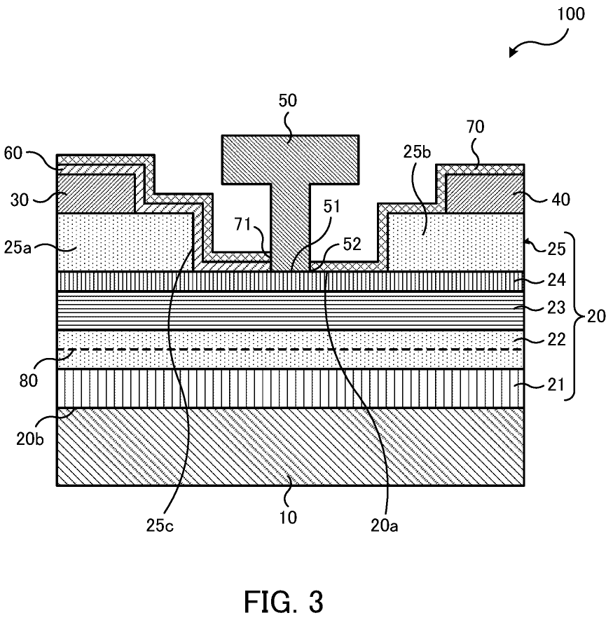

FIG. 3 is a view for describing a semiconductor device according to a first configuration example of a second embodiment. FIG. 3 is a fragmentary schematic sectional view of an example of a semiconductor device.

A semiconductor device 100 illustrated in FIG. 3 is an example of a HEMT. The semiconductor device 100 includes a substrate 10, a semiconductor layer 20, a source electrode 30, a drain electrode 40, a gate electrode 50, an insulating film 60, and a protection film 70.

For example, an InP substrate is used as the substrate 10. The semiconductor layer 20 is formed over the substrate 10. The semiconductor layer 20 is grown over the substrate 10 by the use of the MOCVD method or the like.

The semiconductor layer 20 includes a buffer layer 21, a channel layer 22, an electron supply layer 23, an etching stop layer 24, and a cap layer 25. InAlAs or the like is used for forming the buffer layer 21. InGaAs or the like is used for forming the channel layer 22. InAlAs or the like is used for forming the electron supply layer 23. InP, indium gallium phosphide (InGaP), or the like is used for forming the etching stop layer 24. InGaAs or the like is used for forming the cap layer 25. The buffer layer 21, the channel layer 22, the electron supply layer 23, the etching stop layer 24, and the cap layer 25 are laminated in order over the substrate 10.

For example, the thickness of the channel layer 22 is set in the range of about 9 to 25 nm. For example, the thickness of the electron supply layer 23 is set in the range of about 9 to 25 nm. For example, the thickness of the etching stop layer 24 is set in the range of about 4 to 6 nm. For example, the thickness of the cap layer 25 is set in the range of about 30 to 50 nm. For example, a determined region of each of the electron supply layer 23 and the cap layer 25 is doped with impurities, such as silicon (Si), at a determined concentration.

A 2DEG 80 is generated in the channel layer 22 of the semiconductor layer 20 over which the electron supply layer 23 is laminated. The cap layer 25 includes a recess 25c which communicates with the etching stop layer 24 and a first mesa 25a and a second mesa 25b which are opposite each other with the recess 25c therebetween. In the semiconductor layer 20, the density of the 2DEG 80 generated directly under the first mesa 25a and the second mesa 25b is higher than that of the 2DEG 80 generated directly under the recess 25c. By adjusting the width of the recess 25c, the density of the 2DEG 80 directly under the recess 25c is adjusted so as to be the density of the 2DEG 80 which is able to be controlled by an electric field generated by the gate electrode 50 formed in the recess 25c. The etching stop layer 24 is formed between the electron supply layer 23 and the first mesa 25a, between the electron supply layer 23 and the second mesa 25b, and under the bottom of the recess 25c.

In the semiconductor device 100, the channel layer 22, the electron supply layer 23, the cap layer 25, and the etching stop layer 24 of the semiconductor layer 20 are also referred to as a “first layer”, a “second layer”, a “third layer”, and a “fourth layer”, respectively. In the semiconductor device 100, a surface 20a of the semiconductor layer 20 opposite to the substrate 10 is also referred to as a “first surface” and a surface 20b of the semiconductor layer 20 on the substrate 10 side is also referred to as a “second surface”.

The source electrode 30 and the drain electrode 40 are formed over the cap layer 25 on the surface 20a side of the semiconductor layer 20. The source electrode 30 is formed over the first mesa 25a of the cap layer 25. The drain electrode 40 is formed over the second mesa 25b of the cap layer 25. The source electrode 30 and the drain electrode 40 are located opposite each other with the recess 25c of the cap layer 25 therebetween and apart from each other. The source electrode 30 and the drain electrode 40 are formed by the use of a metal material such as Ti, Pt, or Au. The source electrode 30 and the drain electrode 40 are formed so as to function as an ohmic electrode. The source electrode 30 and the drain electrode 40 are formed over the first mesa 25a and the second mesa 25b, respectively, and the 2DEG 8 generated in the channel layer 22 directly under the first mesa 25a and the second mesa 25b is relatively dense. As a result, a relatively good ohmic connection is realized.

The gate electrode 50 is formed in the recess 25c of the cap layer 25 between the source electrode 30 and the drain electrode 40 on the surface 20a side of the semiconductor layer 20. The gate electrode 50 is located apart from the source electrode 30, the first mesa 25a over which the source electrode 30 is formed, the drain electrode 40, and the second mesa 25b over which the drain electrode 40 is formed. The gate electrode 50 is formed by the use of a metal material such as Ti, Pt, or Au. For example, the gate electrode 50 is formed so as to have a section in the shape of the letter “T”. For example, the gate electrode 50 is formed so as to function as a Schottky electrode. For example, the gate electrode 50 is formed such that an end surface 51 (lower end surface) which faces the surface 20a of the semiconductor layer 20 is in contact with the etching stop layer 24. Alternatively, the gate electrode 50 may be formed over the surface 20a of the semiconductor layer 20 with a gate insulating film (not illustrated) therebetween so as to realize a MIS-type gate structure.

The insulating film 60 is formed on the source electrode 30 side from the gate electrode 50 on the surface 20a side of the semiconductor layer 20 on which the gate electrode 50, the source electrode 30, and the drain electrode 40 are formed. The insulating film 60 covers the recess 25c of the cap layer 25 on the source electrode 30 side from the gate electrode 50, the first mesa 25a, and the source electrode 30. The insulating film 60 covers at least the bottom (etching stop layer 24 exposed on the bottom) of the recess 25c between the gate electrode 50 and the first mesa 25a on the source electrode 30 side from the gate electrode 50. The insulating film 60 contains AlₓO_{y} (y/x<3/2) having oxygen vacancies. The insulating film 60 containing AlₓO_{y} (y/x<3/2) having oxygen vacancies is positively charged. With the semiconductor device 100, the positively charged insulating film 60 is located on the source electrode 30 side from the gate electrode 50. As a result, the density of the 2DEG 80 directly under an area between the gate electrode 50 and the first mesa 25a in the recess 25c increases.

In the semiconductor device 100, the insulating film 60 formed on the source electrode 30 side from the gate electrode 50 is also referred to as a “first insulating film”.

The protection film 70 is formed on the source electrode 30 side and the drain electrode 40 side from the gate electrode 50 on the surface 20a side of the semiconductor layer 20 on which the gate electrode 50, the source electrode 30, and the drain electrode 40 are formed. The gate electrode 50 is formed in an opening portion 71 formed in the protection film 70 so as to communicate with the etching stop layer 24. The protection film 70 covers the insulating film 60 formed on the source electrode 30 side from the gate electrode 50. The protection film 70 covers the recess 25c of the cap layer 25 on the drain electrode 40 side from the gate electrode 50, the second mesa 25b, and the drain electrode 40. The protection film 70 is also referred to as a “passivation film”. A hydrophobic film is used as the protection film 70. For example, an insulating film containing silicon nitride (SiN) is used as the protection film 70. With the semiconductor device 100, adsorption of moisture on or infiltration of moisture into the insulating film 60 formed on the source electrode 30 side from the gate electrode 50 or the semiconductor layer 20 on the drain electrode 40 side from the gate electrode 50 is suppressed by the protection film 70. This suppresses variation in the characteristics of the semiconductor device 100 caused by adsorption or infiltration of moisture.

In the semiconductor device 100, the protection film 70 which covers the insulating film 60 formed on the source electrode 30 side from the gate electrode 50 and the drain electrode 40 side from the gate electrode 50 is also referred to as a “fourth insulating film”.

With the semiconductor device 100, the insulating film 60 which contains AlₓO_{y} (y/x<3/2) having oxygen vacancies and which is positively charged is formed on the source electrode 30 side from the gate electrode 50 on the surface 20a side of the semiconductor layer 20 on which the gate electrode 50, the source electrode 30, and the drain electrode 40 are formed. With the semiconductor device 100, the positively charged insulating film 60 is formed. As a result, the density of the 2DEG 80 directly under the area between the gate electrode 50 and the first mesa 25a increases. That is to say, a conduction band of a bonding portion between the channel layer 22 and the electron supply layer 23 directly under the area between the gate electrode 50 and the first mesa 25a is pushed down due to positive fixed charges in the insulating film 60. As a result, the density of the 2DEG 80 directly under the area between the gate electrode 50 and the first mesa 25a increases.

With the semiconductor device 100, the density of the 2DEG 80 directly under the area between the gate electrode 50 and the first mesa 25a increases because of the insulating film 60. As a result, the resistance of the channel layer 22 between the gate electrode 50 and the source electrode 30 lowers. Accordingly, the resistance of the channel layer 22 between the drain electrode 40 and the source electrode 30 lowers. This increases a current and an output of the semiconductor device 100.

Furthermore, with the semiconductor device 100, the insulating film 60 is not formed on the drain electrode 40 side from the gate electrode 50. Accordingly, with the semiconductor device 100, an increase in the density of the 2DEG 80 directly under the area between the gate electrode 50 and the second mesa 25b is suppressed. As a result, an electric field generated in the semiconductor layer 20 between the gate electrode 50 and the drain electrode 40 is suppressed. In addition, electric field concentration at an edge 52 on the drain electrode 40 side (also referred to as a “drain-side gate edge 52”) of an end surface 51 of the gate electrode 50 is suppressed. This suppresses a drop in the breakdown voltage of the semiconductor device 100.

The insulating film 60 containing AlₓO_{y} (y/x<3/2) having oxygen vacancies is formed on the source electrode 30 side from the gate electrode 50 on the surface 20a side of the semiconductor layer 20 on which the gate electrode 50, the source electrode 30, and the drain electrode 40 are formed. By doing so, a high output and high breakdown voltage semiconductor device 100 is realized.

A method for manufacturing the above semiconductor device 100 will now be described.

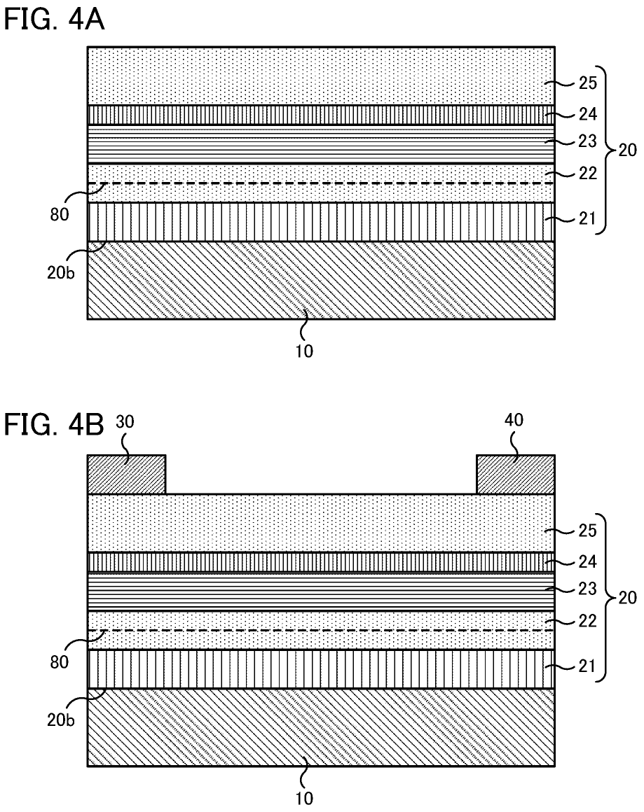

FIGS. 4A through 6B are views for describing a method for manufacturing the semiconductor device according to the first configuration example of the second embodiment. Each of FIGS. 4A, 4B, 5A, 5B, 6A, and 6B is a fragmentary schematic sectional view of an example of a semiconductor device manufacturing process.

In the beginning, the substrate 10 and semiconductor layer 20 illustrated in FIG. 4A are prepared. First, an InP substrate or the like is prepared as the substrate 10. The buffer layer 21, the channel layer 22, the electron supply layer 23, the etching stop layer 24, and the cap layer 25 of the semiconductor layer 20 are formed in order over the prepared substrate 10 by the use of the MOCVD method or the like. For example, the buffer layer 21 of InAlAs, the channel layer 22 of InGaAs, the electron supply layer 23 of InAlAs, the etching stop layer 24 of InP or InGaP, and the cap layer 25 of InGaAs are formed in order.

After the semiconductor layer 20 is formed, element isolation regions (not illustrated) are formed, for example, in the following way. First, a resist mask (not illustrated) having openings over areas in which the element isolation regions are to be formed is formed over the cap layer 25. The cap layer 25 is etched with the resist mask as a mask by the use of, for example, a liquid mixture of phosphoric acid and a hydrogen peroxide solution. This etching is stopped on the etching stop layer 24. Next, the etching stop layer 24 is etched by the use of, for example, hydrochloric acid. This etching is stopped on the electron supply layer 23. After that, the electron supply layer 23 and the channel layer 22 are etched by the use of, for example, a liquid mixture of phosphoric acid and a hydrogen peroxide solution. The element isolation regions are formed in this way. After the element isolation regions are formed, the resist mask is removed.

As illustrated in FIG. 4B, the source electrode 30 and the drain electrode 40 are formed over the semiconductor layer 20 corresponding an element region demarcated by the element isolation regions. When the source electrode 30 and the drain electrode 40 are formed, a resist mask (not illustrated) having openings over areas in which the source electrode 30 and the drain electrode 40 are to be formed is formed over the cap layer 25. After the resist mask is formed, Ti, Pt, and Au are formed in order by the use of an evaporation method. Furthermore, the resist mask, together with Ti, Pt, and Au formed thereover, is removed. The source electrode 30 and the drain electrode 40 are formed over the cap layer 25 by the use of, for example, this lift-off method.

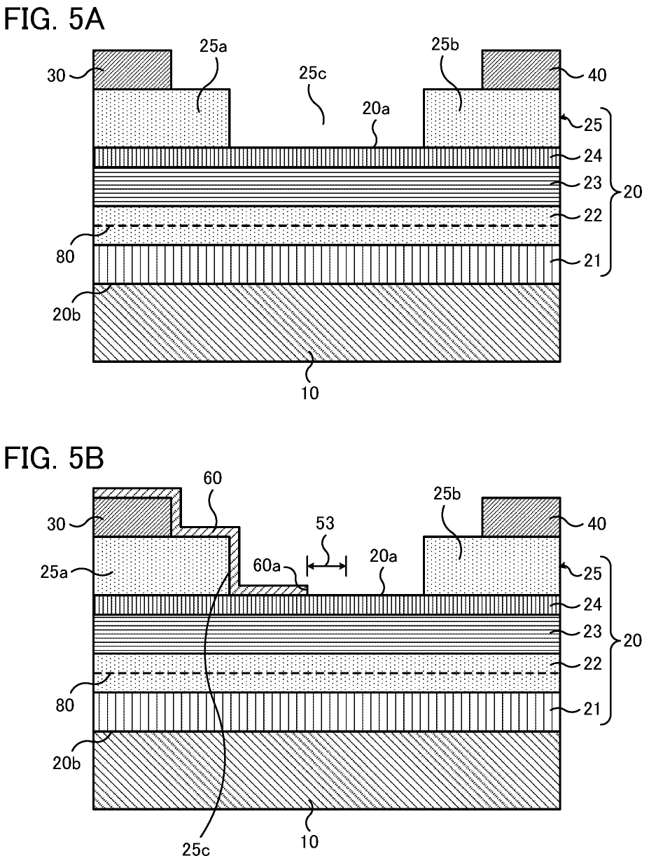

As illustrated in FIG. 5A, after the source electrode 30 and the drain electrode 40 are formed, the recess 25c is formed in the cap layer 25. The recess 25c is formed in an area of the cap layer 25 between the source electrode 30 and the drain electrode 40. When the recess 25c is formed, a resist mask (not illustrated) having an opening over the area in which the recess 25c is to be formed is formed over the cap layer 25 by the use of, for example, an electron-beam lithography technique. The cap layer 25 is etched with the formed resist mask as a mask by the use of, for example, a liquid mixture of phosphoric acid and a hydrogen peroxide solution. This etching is stopped on the etching stop layer 24. The recess 25c is formed in the cap layer 25 by the use of the above method.

By forming the recess 25c, the first mesa 25a and the second mesa 25b of the cap layer 25 are formed. The width of the recess 25c between the first mesa 25a and the second mesa 25b is adjusted and the density of the 2DEG 80 generated in the channel layer 22 directly under the recess 25c is adjusted.

As illustrated in FIG. 5B, after the recess 25c, the first mesa 25a, and the second mesa 25b of the cap layer 25 are formed, the insulating film 60 which covers part of the semiconductor layer 20 and the source electrode 30 is formed on the surface 20a side of the semiconductor layer 20.

When the insulating film 60 is formed, first, an insulating material for the insulating film 60 is formed so as to cover the semiconductor layer 20, the source electrode 30, and the drain electrode 40. AlₓO_{y} (y/x<3/2) having oxygen vacancies is formed as an insulating material for the insulating film 60. Such an insulating material is formed by the use of, for example, an atomic layer deposition (ALD) method so as to cover the semiconductor layer 20, the source electrode 30, and the drain electrode 40.

If the ALD method is used for forming the insulating material for the insulating film 60, then the amount of an Al material supplied and the amount of an O material supplied are adjusted and AlₓO_{y} (y/x<3/2) having oxygen vacancies is formed. Furthermore, AlₓO_{y} (x and y are arbitrary values) formed by the use of the ALD method or another method (such as a CVD method) is reduced by the use of reducing gas such as hydrogen. By doing so, AlₓO_{y} (y/x<3/2) having oxygen vacancies is formed.

The film thickness of the insulating material for the insulating film 60 is not limited. For example, the film thickness of the insulating material is set in the range of 1 to 10 nm. As the film thickness of the insulating material, that is to say, of the insulating film 60 made of the insulating material increases, the influence of positive charges in the insulating film 60 (effect of increasing the density of the 2DEG 80 directly under the insulating film 60) may grow.

Of the insulating material formed in this way so as to cover the semiconductor layer 20, the source electrode 30, and the drain electrode 40, an insulating material in an area 53 in which the gate electrode 50 is to be formed and an insulating material on the drain electrode 40 side from the area 53 are selectively removed. At this time, a resist mask (not illustrated) having an opening over the area 53 and an area on the drain electrode 40 side from the area 53 is formed by the use of, for example, a photolithography technique. The insulating material formed in the area 53 and the area on the drain electrode 40 side from the area 53 is wet-etched with the resist mask as a mask by the use of an alkali-based medical fluid such as tetra-methyl-ammonium hydroxide (TMAH). As a result, as illustrated in FIG. 5B, the insulating film 60 which covers an area on the source electrode 30 side from the area 53 over the semiconductor layer 20 and the source electrode 30 is formed.

A side 60a of the insulating film 60 formed by this wet etching may be inclined such that the thickness of the insulating film 60 decreases toward the drain electrode 40 side.

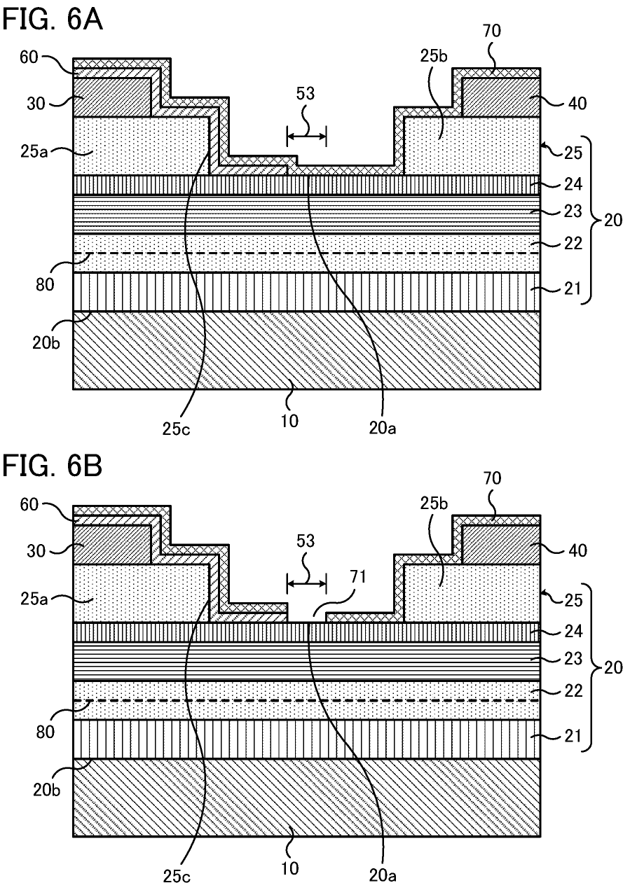

As illustrated in FIG. 6A, after the insulating film 60 is formed, the protection film 70 is formed so as to cover the insulating film 60 formed over the semiconductor layer 20, the semiconductor layer 20 exposed from the insulating film 60, and the drain electrode 40. For example, the protection film 70 of SiN is formed. The protection film 70 is formed by the use of, for example, plasma CVD method. For example, the thickness of the protection film 70 is set in the range of 2 to 500 nm. The protection film 70 may be formed by the use of the ALD method, a sputtering method, or the like other than the plasma CVD method.

As illustrated in FIG. 6B, after the protection film 70 is formed, an opening portion 71 is formed in the protection film 70. The opening portion 71 of the protection film 70 is formed in the area 53 in the recess 25c of the cap layer 25 in which the gate electrode 50 is to be formed. When the opening portion 71 is formed, a resist mask (not illustrated) having an opening over the area 53 is formed. Dry etching is performed with the resist mask as a mask by the use of fluorine-based gas. As a result, the opening portion 71 which communicates with the etching stop layer 24 is formed.

As illustrated in FIG. 3, after the opening portion 71 of the protection film 70 is formed, the gate electrode 50 is formed. When the gate electrode 50 is formed, a resist mask (not illustrated) having an opening over the area 53 in which the gate electrode 50 is to be formed, that is to say, over the opening portion 71 of the protection film 70 is formed over the protection film 70. For example, the electron-beam lithography technique is used for forming the resist mask. For example, a multilayered resist mask is formed as the resist mask. After the resist mask is formed, Ti, Pt, and Au are formed in order by the use of the evaporation method. Furthermore, the resist mask, together with Ti, Pt, and Au formed thereover, is removed. The gate electrode 50 is formed by the use of, for example, this lift-off method. By forming the gate electrode 50, the semiconductor device 100 illustrated in FIG. 3 is manufactured.

After the gate electrode 50 is formed, a passivation film, a wiring, and the like may be formed further.

A case where an InP substrate is used as the substrate 10 is taken as an example. However, various substrates other than an InP substrate may be used as the substrate 10. For example, an InP-based compound semiconductor substrate or a GaAs-based compound semiconductor substrate, such as a GaAs substrate, may be used. A material for or the structure of the buffer layer 21 formed between the substrate 10 and the channel layer 22 is properly adjusted on the basis of the type of the substrate 10 used. That is to say, the buffer layer 21 that enables the channel layer 22 to grow thereon is formed over the substrate 10.

Next, a second configuration example of the semiconductor device according to the second embodiment will be described.

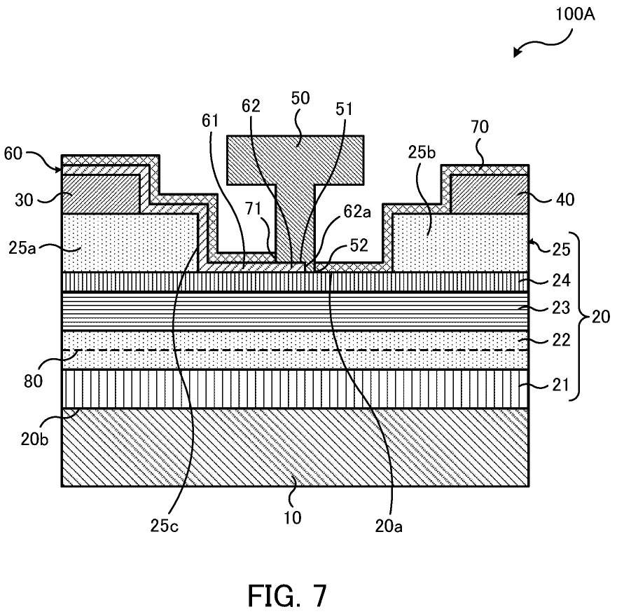

FIG. 7 is a view for describing a semiconductor device according to a second configuration example of the second embodiment. FIG. 7 is a fragmentary schematic sectional view of an example of a semiconductor device.

A semiconductor device 100A illustrated in FIG. 7 is an example of a HEMT. An insulating film 60 formed in the semiconductor device 100A includes a first portion 61 formed on the source electrode 30 side from a gate electrode 50 and a second portion 62 formed between a surface 20a of a semiconductor layer 20 and an end surface 51 of the gate electrode 50. The second portion 62 connects with the first portion 61. An edge 62a on the drain electrode 40 side of the second portion 62 is situated on the source electrode 30 side from a gate edge 52 on the drain electrode 40 side. With the semiconductor device 100A, the second portion 62, which is part of the insulating film 60, extends from the source electrode 30 side to a position between the surface 20a of the semiconductor layer 20 and the end surface 51 of the gate electrode 50 and does not reach the gate edge 52 on the drain electrode 40 side. With the semiconductor device 100A, it may safely be said that the edge 62a of the insulating film 60 is at a position inside the gate edge 52 on the drain electrode 40 side. For example, an insulating film containing AlₓO_{y} (y/x<3/2) having oxygen vacancies is formed as the insulating film 60.

In the semiconductor device 100A, a channel layer 22, an electron supply layer 23, a cap layer 25, and an etching stop layer 24 of the semiconductor layer 20 are also referred to as a “first layer”, a “second layer”, a “third layer”, and a “fourth layer”, respectively. In the semiconductor device 100A, the surface 20a of the semiconductor layer 20 opposite to a substrate 10 is also referred to as a “first surface” and a surface 20b of the semiconductor layer 20 on the substrate 10 side is also referred to as a “second surface”. In the semiconductor device 100A, the first portion 61, of the insulating film 60, formed on the source electrode 30 side from the gate electrode 50 is also referred to as a “first insulating film”. In the semiconductor device 100A, the second portion 62, of the insulating film 60, formed between the surface 20a of the semiconductor layer 20 and the end surface 51 of the gate electrode 50 is also referred to as a “second insulating film”.

With the semiconductor device 100A, the second portion 62 of the insulating film 60 functions as a gate insulating film. As a result, with the semiconductor device 100A, generation of a gate leakage current is suppressed.

With the semiconductor device 100A, the density of a 2DEG 80 directly under an area between the gate electrode 50 and a first mesa 25a and part of the gate electrode 50 increases because of the first portion 61 and the second portion 62 of the insulating film 60 containing AlₓO_{y} (y/x<3/2) having oxygen vacancies. This increases a current and an output of the semiconductor device 100A.

With the semiconductor device 100A, the density of the 2DEG 80 directly under an area between the gate electrode 50 and a second mesa 25b is relatively lower than that of the 2DEG 80 directly under the area between the gate electrode 50 and the first mesa 25a. As a result, an electric field generated in the semiconductor layer 20 between the gate electrode 50 and the drain electrode 40 is suppressed. In addition, with the semiconductor device 100A, the edge 62a of the second portion 62 of the insulating film 60 does not reach the gate edge 52 on the drain electrode 40 side. Accordingly, even if the second portion 62 contains AlₓO_{y} (y/x<3/2) having oxygen vacancies, an increase in the density of the 2DEG 80 directly under the gate edge 52 on the drain electrode 40 side is suppressed and electric field concentration at the gate edge 52 on the drain electrode 40 side is suppressed. This suppresses a drop in the breakdown voltage of the semiconductor device 100A.

As described later, the number of oxygen vacancies in the second portion 62 of the insulating film 60 may be made smaller than that of oxygen vacancies in the first portion 61 or the second portion 62 may have no oxygen vacancies.

The insulating film 60 including the above first portion 61 and second portion 62 is used and a high output and high breakdown voltage semiconductor device 100A is realized.

Next, a method for manufacturing the above semiconductor device 100A will be described.

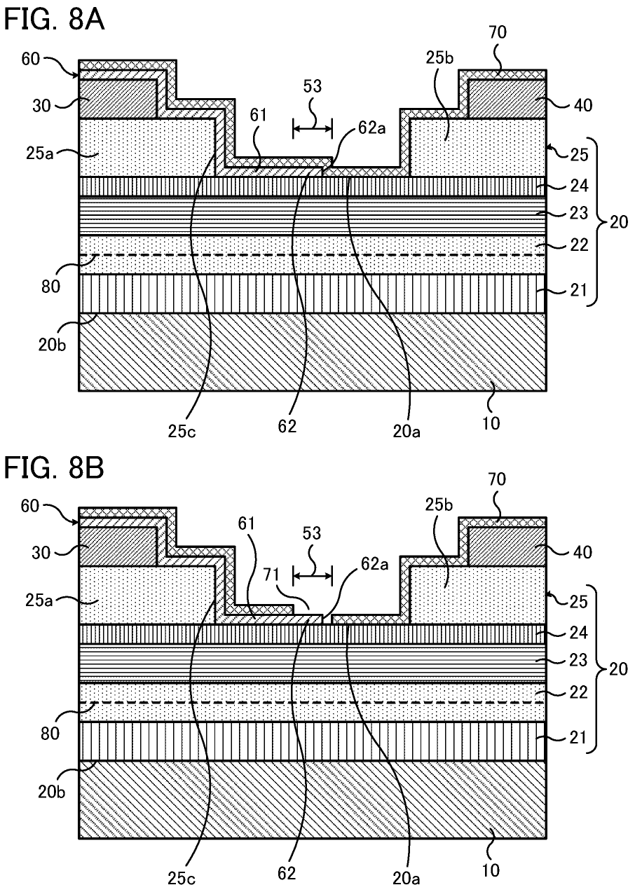

FIGS. 8A and 8B are views for describing a method for manufacturing the semiconductor device according to the second configuration example of the second embodiment. Each of FIGS. 8A and 8B is a fragmentary schematic sectional view of an example of a semiconductor device manufacturing process.

When the semiconductor device 100A illustrated in FIG. 7 is manufactured, the insulating film 60 is formed in an area illustrated in FIG. 8A after the processes illustrated in FIGS. 4A, 4B, and 5A. That is to say, the insulating film 60 is formed such that the first portion 61 is formed on the source electrode 30 side from an area 53 in which the gate electrode 50 is to be formed and such that the second portion 62 is formed in part of the area 53. This insulating film 60 is formed in accordance with the step described in FIG. 5B. As a result, the insulating film 60 illustrated in FIG. 8A is formed. This insulating film 60 includes the first portion 61 which covers the source electrode 30 side of the semiconductor layer 20 from the area 53 and the source electrode 30 and the second portion 62 which covers the part of the area 53. For example, an insulating film containing AlₓO_{y} (y/x<3/2) having oxygen vacancies is formed as the insulating film 60. For example, the thickness of the insulating film 60 is set in the range of 1 to 10 nm. If the second portion 62 is made to function as a gate insulating film, then the thickness of the insulating film 60 is set in the range of, for example, 1 to 5 nm. For example, the thickness of the insulating film 60 is set to 2 nm.

As illustrated in FIG. 8A, after the insulating film 60 is formed, a protection film 70 is formed so as to cover the insulating film 60 formed over the semiconductor layer 20, the semiconductor layer 20 exposed from the insulating film 60, and the drain electrode 40. For example, the protection film 70 containing SiN is formed. As illustrated in FIG. 8B, an opening portion 71 is formed in the area 53 of the protection film 70 in which the gate electrode 50 is to be formed. The protection film 70 and the opening portion 71 are formed in accordance with the steps described in FIGS. 6A and 6B, respectively. By forming the opening portion 71, the second portion 62 of the insulating film 60 is exposed in the area 53. Furthermore, the gate electrode 50 is formed in the area 53 in which the second portion 62 of the insulating film 60 is exposed. As a result, the semiconductor device 100A illustrated in FIG. 7 is manufactured.

After the gate electrode 50 is formed, a passivation film, a wiring, and the like may be formed further.

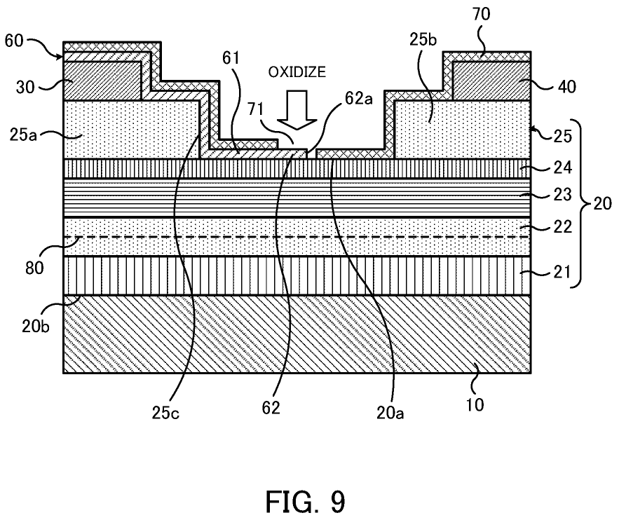

FIG. 9 is a view for describing further the method for manufacturing the semiconductor device according to the second configuration example of the second embodiment. FIG. 9 is a fragmentary schematic sectional view of an example of a semiconductor device manufacturing process.

If the second portion 62 of the insulating film 60 in the semiconductor device 100A which functions as a gate insulating film contains AlₓO_{y} (y/x<3/2) having oxygen vacancies, then the oxygen vacancies may become electron trap sites.

Accordingly, as illustrated in FIG. 9, after the opening portion 71 of the protection film 70 illustrated in FIG. 8B is formed and before the gate electrode 50 is formed, the second portion 62 of the insulating film 60 exposed from the opening portion 71 may be oxidized to decrease the number of the oxygen vacancies. For example, the second portion 62 exposed from the opening portion 71 is oxidized by the use of water vapor. Because at this time the first portion 61 of the insulating film 60 is covered with the protection film 70, oxidization of the first portion 61 is suppressed. By selectively oxidizing the second portion 62 in this way, the number of the oxygen vacancies in the second portion 62 which functions as a gate insulating film becomes smaller than that of oxygen vacancies in the first portion 61 formed on the source electrode 30 side from the gate electrode 50.

As stated above, the insulating film 60 of the semiconductor device 100A may include the first portion 61 having a relatively large number of oxygen vacancies and the second portion 62 having a relatively small number of oxygen vacancies or no oxygen vacancies. That is to say, with the semiconductor device 100A, the insulating film 60 in which the composition ratio of O to Al, or y/x, of AlₓO_{y} contained in the second portion 62 is larger than the composition ratio of O to Al, or y/x, of AlₓO_{y} contained in the first portion 61 may be formed. This suppresses electron traps in the second portion 62. Accordingly, variation in the characteristics, such as a shift in the threshold voltage, of the semiconductor device 100A caused by electron traps in the second portion 62 is suppressed.

Furthermore, if the second portion 62 of the insulating film 60 of the semiconductor device 100A has a relatively small number of oxygen vacancies or no oxygen vacancies, then the influence of positive charges in the second portion 62 is suppressed and an increase in the density of the 2DEG 80 directly under the gate electrode 50 is suppressed. Furthermore, an increase in the density of the 2DEG 80 directly under the gate edge 52 on the drain electrode 40 side is effectively suppressed compared with a case where the second portion 62 has a relatively large number of oxygen vacancies. As a result, electric field concentration at the gate edge 52 on the drain electrode 40 side is suppressed more effectively and a drop in the breakdown voltage of the semiconductor device 100A is suppressed more effectively.

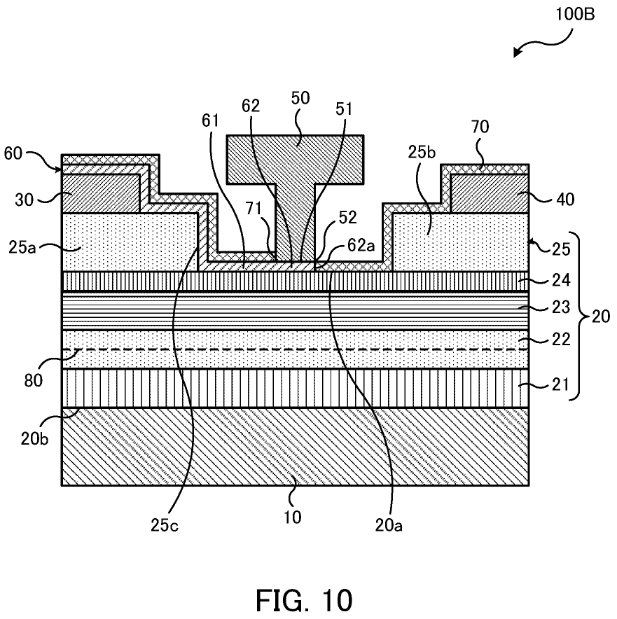

FIG. 10 is a view for describing further the semiconductor device according to the second configuration example of the second embodiment. FIG. 10 is a fragmentary schematic sectional view of an example of the semiconductor device.

A semiconductor device 100B illustrated in FIG. 10 is an example of a HEMT. With the semiconductor device 100B, an insulating film 60 includes a first portion 61 and a second portion 62 and an edge 62a on the drain electrode 40 side of the second portion 62 is situated at a gate edge 52 on the drain electrode 40 side. When the semiconductor device 100B is manufactured, the insulating film 60 is formed such that the second portion 62 is formed in the whole of the area 53 in which the gate electrode 50 is to be formed in the method for manufacturing the semiconductor device 100A described in FIGS. 8A and 8B and the like. A method for manufacturing the semiconductor device 100B differs from the method for manufacturing the above semiconductor device 100A only in that the insulating film 60 is formed in this way.

In the semiconductor device 100B, a channel layer 22, an electron supply layer 23, a cap layer 25, and an etching stop layer 24 of a semiconductor layer 20 are also referred to as a “first layer”, a “second layer”, a “third layer”, and a “fourth layer”, respectively. In the semiconductor device 100B, a surface 20a of the semiconductor layer 20 opposite to a substrate 10 is also referred to as a “first surface” and a surface 20b of the semiconductor layer 20 on the substrate 10 side is also referred to as a “second surface”. In the semiconductor device 100B, the first portion 61, of the insulating film 60, formed on the source electrode 30 side from the gate electrode 50 is also referred to as a “first insulating film”. In the semiconductor device 100B, the second portion 62, of the insulating film 60, formed between the surface 20a of the semiconductor layer 20 and an end surface 51 of the gate electrode 50 is also referred to as a “second insulating film”.

With the semiconductor device 100B illustrated in FIG. 10, a high output and a high breakdown voltage are realized by the insulating film 60 including the first portion 61 and the second portion 62. This is the same with the above semiconductor device 100A.

With the semiconductor device 100B, the edge 62a on the drain electrode 40 side of the second portion 62 is situated at the gate edge 52 on the drain electrode 40 side at which electric field concentration relatively tends to occur. Accordingly, with the semiconductor device 100B, the number of oxygen vacancies in the second portion 62 may be made smaller than that of oxygen vacancies in the first portion 61, for example, by the method of oxidizing the second portion 62 illustrated in FIG. 9. If the number of oxygen vacancies in the second portion 62 having the edge 62a which is situated at the gate edge 52 on the drain electrode 40 side is made smaller than that of oxygen vacancies in the first portion 61, then the influence of positive charges in the second portion 62 is suppressed and an increase in the density of a 2DEG 80 directly under the gate edge 52 on the drain electrode 40 side is suppressed. As a result, electric field concentration at the gate edge 52 on the drain electrode 40 side is suppressed and a drop in the breakdown voltage of the semiconductor device 100B caused by the electric field concentration is suppressed. If the number of oxygen vacancies in the second portion 62 is made smaller than that of oxygen vacancies in the first portion 61 in the semiconductor device 100B, then electron traps in the second portion 62 which functions as a gate insulating film are also suppressed.

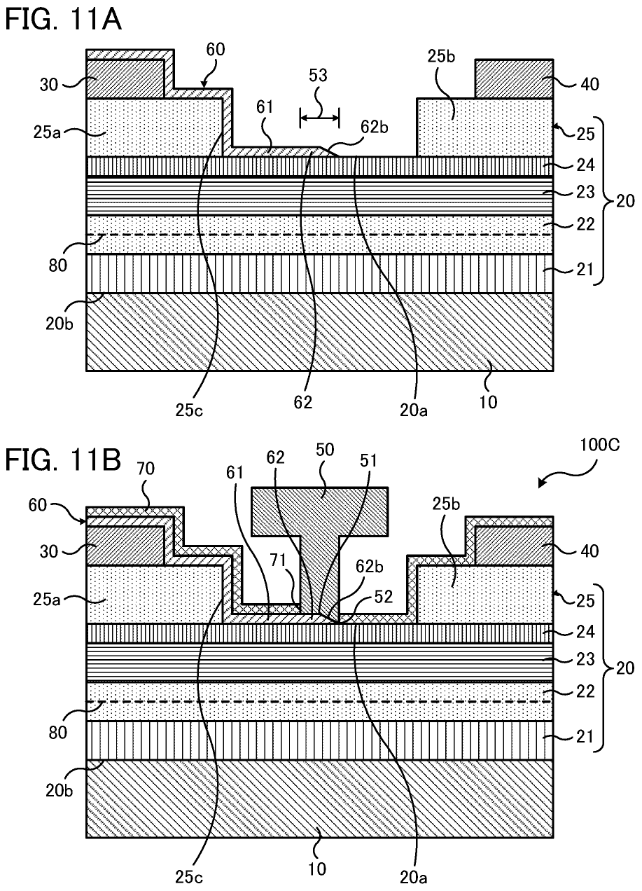

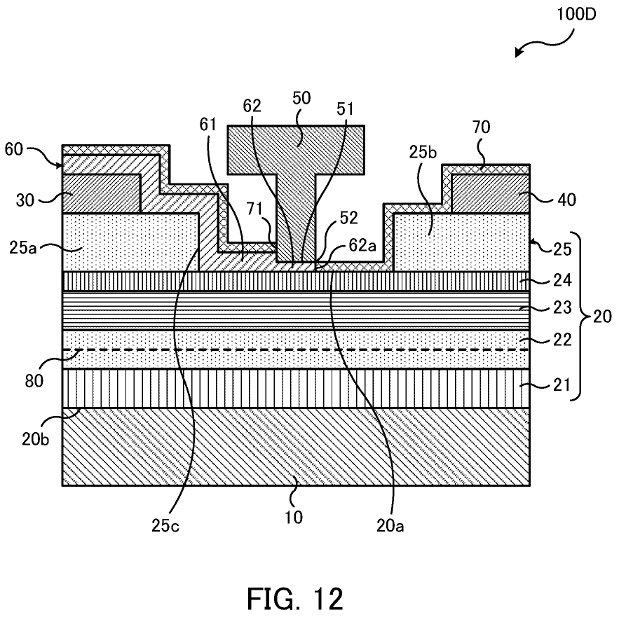

By the way, as the thickness of the insulating film 60 containing AlₓO_{y} (y/x<3/2) having oxygen vacancies increases, the influence of positive charges in the insulating film 60 may grow. Accordingly, structures illustrated in FIGS. 11A and 11B and FIG. 12 may be adopted.

FIGS. 11A and 11B are views for describing a modification of the semiconductor device according to the second configuration example of the second embodiment. FIG. 11A is a fragmentary schematic sectional view of an example of a semiconductor device manufacturing process. FIG. 11B is a fragmentary schematic sectional view of an example of a semiconductor device.

When an insulating film 60 is formed in accordance with the step described in FIG. 8A (and FIG. 5B), the insulating film 60 including a second portion 62 illustrated in FIG. 11A may be formed. That is to say, as illustrated in FIG. 11A, a side 62b on the drain electrode 40 side of the second portion 62 formed in an area 53 in which a gate electrode 50 is to be formed may be inclined such that the thickness of the second portion 62 decreases toward the drain electrode 40 side.

As stated above, when the insulating film 60 is formed, first, an insulating material for the insulating film 60 is formed on the surface 20a side of a semiconductor layer 20 by the use of the ALD method so as to cover the semiconductor layer 20, a source electrode 30, and the drain electrode 40. Furthermore, part of the insulating material is wet-etched by the use of a medical fluid and the insulating film 60 including a first portion 61 and the second portion 62 illustrated in FIG. 11A is formed. By adjusting conditions, such as the type of the medical fluid, immersion temperature, and immersion time, at the time of the wet etching, the second portion 62 having the inclined side 62b is obtained.

After the insulating film 60 including the above second portion 62 is formed, a protection film 70 and an opening portion 71 are formed in accordance with the steps illustrated in FIGS. 8A and 8B, respectively. Furthermore, the gate electrode 50 is formed over the second portion 62 exposed by forming the opening portion 71. As a result, a semiconductor device 100C (example of a HEMT) illustrated in FIG. 11B is obtained.

In the semiconductor device 100C, a channel layer 22, an electron supply layer 23, a cap layer 25, and an etching stop layer 24 of the semiconductor layer 20 are also referred to as a “first layer”, a “second layer”, a “third layer”, and a “fourth layer”, respectively. In the semiconductor device 100C, the surface 20a of the semiconductor layer 20 opposite to a substrate 10 is also referred to as a “first surface” and a surface 20b of the semiconductor layer 20 on the substrate 10 side is also referred to as a “second surface”. In the semiconductor device 100C, the first portion 61, of the insulating film 60, formed on the source electrode 30 side from the gate electrode 50 is also referred to as a “first insulating film”. In the semiconductor device 100C, the second portion 62, of the insulating film 60, formed between the surface 20a of the semiconductor layer 20 and an end surface 51 of the gate electrode 50 is also referred to as a “second insulating film”.

With the semiconductor device 100C illustrated in FIG. 11B, the second portion 62 of the insulating film 60 which functions as a gate insulating film has the inclined side 62b. That is to say, the thickness of the second portion 62 decreases toward the drain electrode 40 side. As a result, even if the second portion 62 contains AlₓO_{y} (y/x<3/2) having oxygen vacancies, the influence of positive charges in the second portion 62 is reduced directly under the inclined side 62b. Accordingly, an increase in the density of a 2DEG 80 directly under the inclined side 62b is suppressed. This suppresses a drop in the breakdown voltage of the semiconductor device 100C.

The second portion 62 of the insulating film 60 of the semiconductor device 100C having the inclined side 62b (FIG. 11A) may be oxidized in accordance with the step illustrated in FIG. 9 after the opening portion 71 of the protection film 70 is formed and before the gate electrode 50 is formed. This suppresses an increase in the density of the 2DEG 80 directly under the gate electrode 50 and suppresses electron traps in the second portion 62.

In accordance with the example of FIGS. 11A and 11B, a side 62b of the second portion 62 may also be inclined in the semiconductor device 100A of FIG. 7 in which the edge 62a of the second portion 62 of the insulating film 60 does not reach the gate edge 52 on the drain electrode 40 side.

FIG. 12 is a view for describing another modification of the semiconductor device according to the second configuration example of the second embodiment. FIG. 12 is a fragmentary schematic sectional view of an example of a semiconductor device.

A semiconductor device 100D illustrated in FIG. 12 is an example of a HEMT. With the semiconductor device 100D, an insulating film 60 includes a first portion 61 and a second portion 62 and the thickness of the second portion 62 is less than that of the first portion 61.

For example, the semiconductor device 100D is manufactured by the use of the following method. That is to say, in accordance with the step illustrated in FIG. 8A, the insulating film 60 and a protection film 70 are formed. Next, in accordance with the step illustrated in FIG. 8B, an opening portion 71 is formed. Furthermore, part of the second portion 62 is removed with the protection film 70 in which the opening portion 71 is formed as a mask. By doing so, the second portion 62 is thinned. In addition, a gate electrode 50 is formed over the second portion 62 exposed by forming the opening portion 71 and thinned. For example, this method is used for obtaining the semiconductor device 100D illustrated in FIG. 12.

In the semiconductor device 100D, a channel layer 22, an electron supply layer 23, a cap layer 25, and an etching stop layer 24 of a semiconductor layer 20 are also referred to as a “first layer”, a “second layer”, a “third layer”, and a “fourth layer”, respectively. In the semiconductor device 100D, a surface 20a of the semiconductor layer 20 opposite to a substrate 10 is also referred to as a “first surface” and a surface 20b of the semiconductor layer 20 on the substrate 10 side is also referred to as a “second surface”. In the semiconductor device 100D, the first portion 61, of the insulating film 60, formed on the source electrode 30 side from the gate electrode 50 is also referred to as a “first insulating film”. In the semiconductor device 100D, the second portion 62, of the insulating film 60, formed between the surface 20a of the semiconductor layer 20 and an end surface 51 of the gate electrode 50 is also referred to as a “second insulating film”.

With the semiconductor device 100D illustrated in FIG. 12, the thickness of the second portion 62 of the insulating film 60 is less than that of the first portion 61. As a result, even if the second portion 62 contains AlₓO_{y} (y/x<3/2) having oxygen vacancies, the influence of positive charges in the second portion 62 is reduced directly under the gate electrode 50. Accordingly, an increase in the density of a 2DEG 80 directly under the gate electrode 50 is suppressed. This suppresses a drop in the breakdown voltage of the semiconductor device 100D.

With the semiconductor device 100D, for example, the thickness of the insulating film 60 is set in the range of 1 to 10 nm. The thickness of the second portion 62 is set such that the second portion 62 effectively functions as a gate insulating film, that is to say, such that an electric field generated by the gate electrode 50 is applied to the channel layer 22 and such that a gate leakage current is suppressed. The thickness of the second portion 62 is preferably set in the range of 1 to 5 nm. For example, the thickness of the second portion 62 is set to 2 nm. The thickness of the first portion 61 need only be more than that of the second portion 62. As the thickness of the first portion 61 is increased, it is expected that the amount of positive charges in the first portion 61 will increase and that the density of the 2DEG 80 will increase by the influence of the positive charges.

With the semiconductor device 100D, the second portion 62 of the insulating film 60 having a relatively small thickness may be oxidized in accordance with the step illustrated in FIG. 9 after the opening portion 71 of the protection film 70 is formed and before the gate electrode 50 is formed. This suppresses an increase in the density of the 2DEG 80 directly under the gate electrode 50 more effectively and suppresses electron traps in the second portion 62.

In accordance with the example of FIG. 12, the thickness of the second portion 62 may also be made less than that of the first portion 61 in the semiconductor device 100A of FIG. 7 in which the edge 62a of the second portion 62 of the insulating film 60 does not reach the gate edge 52 on the drain electrode 40 side.

Next, a third configuration example of the semiconductor device according to the second embodiment will be described.

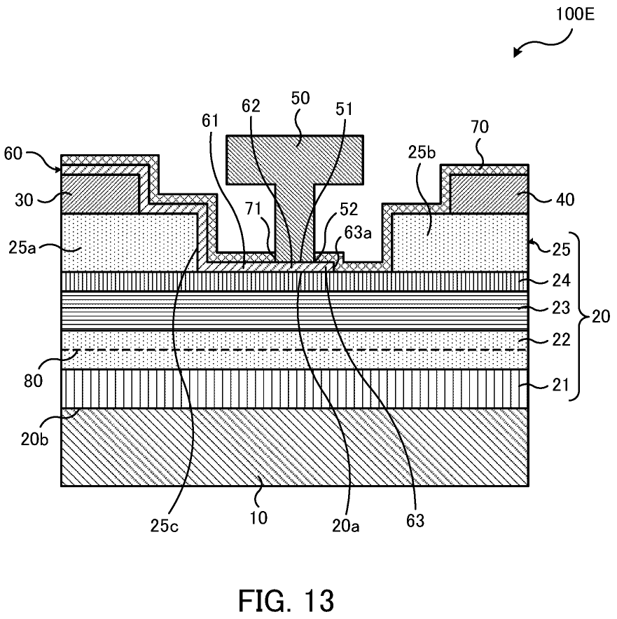

FIG. 13 is a view for describing a semiconductor device according to a third configuration example of the second embodiment. FIG. 13 is a fragmentary schematic sectional view of an example of a semiconductor device.

A semiconductor device 100E illustrated in FIG. 13 is an example of a HEMT. With the semiconductor device 100E, an insulating film 60 including a first portion 61, a second portion 62, and a third portion 63 is formed. The first portion 61 is formed on the source electrode 30 side from a gate electrode 50. The second portion 62 connects with the first portion 61 and is formed between a surface 20a of a semiconductor layer 20 and an end surface 51 of the gate electrode 50. The third portion 63 connects with the second portion 62 and is formed on the drain electrode 40 side from the gate electrode 50. For example, the third portion 63 extends from the gate electrode 50 to a position that does not reach a second mesa 25b of a cap layer 25 over which the drain electrode 40 is formed. For example, the third portion 63 is formed such that an edge 63a on the drain electrode 40 side of the third portion 63 is situated in an area extending for half of the distance between the gate electrode 50 and the second mesa 25b from the gate electrode 50. For example, an insulating film containing AlₓO_{y} (y/x<3/2) having oxygen vacancies is formed as the insulating film 60.

In the semiconductor device 100E, a channel layer 22, an electron supply layer 23, a cap layer 25, and an etching stop layer 24 of the semiconductor layer 20 are also referred to as a “first layer”, a “second layer”, a “third layer”, and a “fourth layer”, respectively. In the semiconductor device 100E, the surface 20a of the semiconductor layer 20 opposite to a substrate 10 is also referred to as a “first surface” and a surface 20b of the semiconductor layer 20 on the substrate 10 side is also referred to as a “second surface”. In the semiconductor device 100E, the first portion 61, of the insulating film 60, formed on the source electrode 30 side from the gate electrode 50 is also referred to as a “first insulating film”. In the semiconductor device 100E, the second portion 62, of the insulating film 60, formed between the surface 20a of the semiconductor layer 20 and an end surface 51 of the gate electrode 50 is also referred to as a “second insulating film”. In the semiconductor device 100E, the third portion 63, of the insulating film 60, formed on the drain electrode 40 side from the gate electrode 50 is also referred to as a “third insulating film”.

With the semiconductor device 100E, the third portion 63 of the insulating film 60 is formed on the drain electrode 40 side from the gate electrode 50 and extends to a position which does not reach the second mesa 25b. As a result, an increase in the density of a 2DEG 80 directly under an area between the gate electrode 50 and the second mesa 25b is suppressed, compared with a case where the insulating film 60 containing AlₓO_{y} (y/x<3/2) having oxygen vacancies extends from the gate electrode 50 to the second mesa 25b. Accordingly, an electric field generated in the semiconductor layer 20 between the gate electrode 50 and the drain electrode 40 is suppressed and a drop in the breakdown voltage of the semiconductor device 100E is suppressed. In a recess 25c of the semiconductor device 100E, the density of the 2DEG 80 directly under the insulating film 60 increases because of the insulating film 60 containing AlₓO_{y} (y/x<3/2) having oxygen vacancies. This increases a current and an output of the semiconductor device 100E.

The insulating film 60 including the above first portion 61, second portion 62, and third portion 63 is used and a high output and high breakdown voltage semiconductor device 100E is realized.

Next, a method for manufacturing the above semiconductor device 100E will be described.

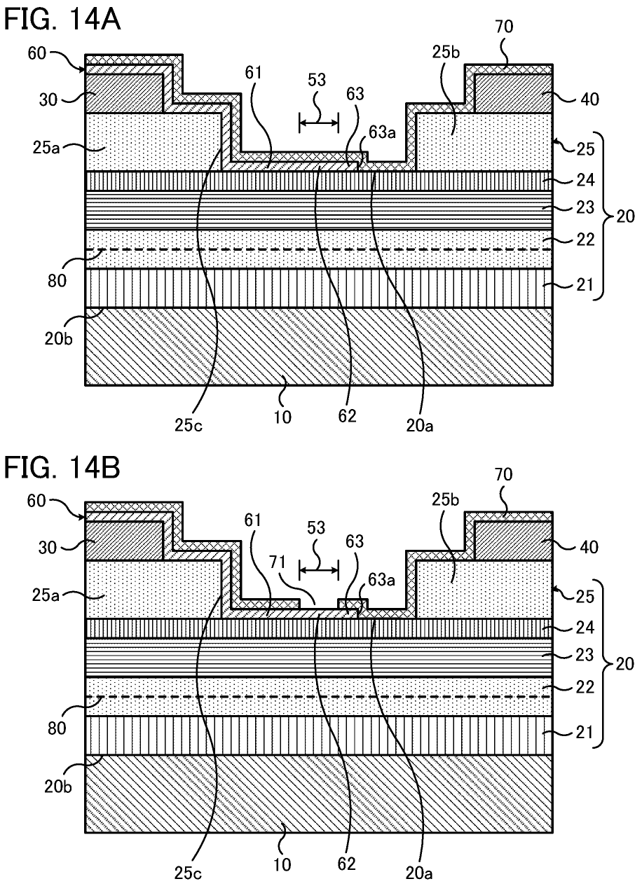

FIGS. 14A and 14B are views for describing a method for manufacturing the semiconductor device according to the third configuration example of the second embodiment. Each of FIGS. 14A and 14B is a fragmentary schematic sectional view of an example of a semiconductor device manufacturing process.

When the semiconductor device 100E illustrated in FIG. 13 is manufactured, the insulating film 60 is formed in an area illustrated in FIG. 14A after the steps illustrated in FIGS. 4A, 4B, and 5A. That is to say, the insulating film 60 is formed such that the first portion 61 is formed on the source electrode 30 side from an area 53 in which the gate electrode 50 is to be formed, such that the second portion 62 is formed in the area 53, and such that the third portion 63 is formed on the drain electrode 40 side from the area 53. The insulating film 60 is formed in accordance with the step described in FIG. 5B. As a result, the insulating film 60 illustrated in FIG. 14A and including the first portion 61 which covers an area on the source electrode 30 side from the area 53 and the source electrode 30, the second portion 62 which covers the area 53, and the third portion 63 which covers part of an area on the drain electrode 40 side from the area 53 is formed. For example, an insulating film containing AlₓO_{y} (y/x<3/2) having oxygen vacancies is formed as the insulating film 60. For example, the thickness of the insulating film 60 is set in the range of 1 to 10 nm. For example, if the second portion 62 of the insulating film 60 functions as a gate insulating film, then the thickness of the insulating film 60 is set in the range of 1 to 5 nm. For example, the thickness of the insulating film 60 is set to 2 nm.

As illustrated in FIG. 14A, after the insulating film 60 is formed, a protection film 70 is formed so as to cover the insulating film 60 formed over the semiconductor layer 20, the semiconductor layer 20 exposed from the insulating film 60, and the drain electrode 40. For example, the protection film 70 containing SiN is formed. As illustrated in FIG. 14B, an opening portion 71 is formed in the area 53 of the protection film 70 in which the gate electrode 50 is to be formed. The protection film 70 and the opening portion 71 are formed in accordance with the steps described in FIGS. 6A and 6B, respectively. By forming the opening portion 71, the second portion 62 of the insulating film 60 is exposed in the area 53. Furthermore, the gate electrode 50 is formed in the area 53 in which the second portion 62 of the insulating film 60 is exposed. As a result, the semiconductor device 100E illustrated in FIG. 13 is manufactured.

After the gate electrode 50 is formed, a passivation film, a wiring, and the like may be formed further.

With the semiconductor device 100E, for example, the number of oxygen vacancies in the second portion 62 may be made smaller than that of oxygen vacancies in the first portion 61 by the use of the method for oxidizing the second portion 62 illustrated in FIG. 9. This suppresses electron traps in the second portion 62 which functions as a gate insulating film, and suppresses an increase in the density of the 2DEG 80 directly under the second portion 62. Furthermore, with the semiconductor device 100E, for example, not only the second portion 62 but also the third portion 63 may be exposed from the protection film 70 and be oxidized. By doing so, the number of oxygen vacancies in the third portion 63 is made smaller than that of oxygen vacancies in the first portion 61. This suppresses an increase in the density of the 2DEG 80 directly under the third portion 63, suppresses an increase in the density of the 2DEG 80 directly under the area between the gate electrode 50 and the second mesa 25b, and suppresses a drop in the breakdown voltage. If the number of oxygen vacancies in the third portion 63 is made smaller than that of oxygen vacancies in the first portion 61, then the third portion 63 may be formed from the gate electrode 50 to the second mesa 25b or from the gate electrode 50 to the drain electrode 40. Furthermore, the third portion 63 may be formed from the gate electrode 50 to the drain electrode 40 and be formed so as to cover the drain electrode 40.

With the semiconductor device 100E, the thickness of the second portion 62 of the insulating film 60 may be made less than that of the first portion 61 in accordance with the example of FIG. 12. In addition, with the semiconductor device 100E, the thickness of the third portion 63 of the insulating film 60 may be made less than that of the first portion 61. Moreover, the thickness of the second portion 62 and the third portion 63 of the insulating film 60 may be made less than that of the first portion 61. Even if the insulating film 60 contains AlₓO_{y} (y/x<3/2) having oxygen vacancies, this reduces the influence of positive charges in the second portion 62 or the third portion 63 having less thickness, suppresses an increase in the density of the 2DEG 80, and suppresses a drop in the breakdown voltage.

In the semiconductor device 100E, a side (edge 63a) on the drain electrode 40 side of the third portion 63 of the insulating film 60 may be inclined.

With the above semiconductor device 100, 100A, 100B, 100C, 100D, or 100E, an asymmetrical arrangement may be adopted. That is to say, the distance between the gate electrode 50 and the second mesa 25b on the drain electrode 40 side may be longer than the distance between the gate electrode 50 and the first mesa 25a on the source electrode 30 side. By adopting this asymmetrical arrangement, the breakdown voltage of the semiconductor device 100, 100A, 100B, 100C, 100D, or 100E is raised further.

### Third Embodiment

Evaluation results of the characteristics of a semiconductor device will now be described as a third embodiment.

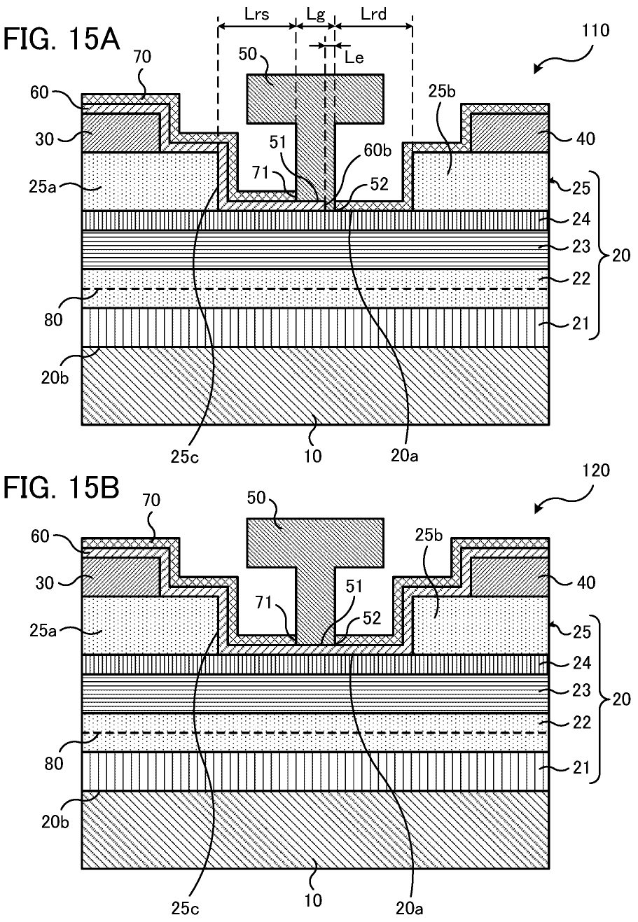

FIGS. 15A and 15B are views for describing a semiconductor device used for characteristic evaluation. Each of FIGS. 15A and 15B is a fragmentary schematic sectional view of a configuration example of a semiconductor device.

A semiconductor device 110 illustrated in FIG. 15A and a semiconductor device 120 illustrated in FIG. 15B are used for characteristic evaluation. Hereinafter the semiconductor devices 110 and 120 are also referred to as a “practical example” and a “comparative example”, respectively.

As illustrated in FIG. 15A, with the semiconductor device 110, the gate length of a gate electrode 50 is defined as Lg. Furthermore, with the semiconductor device 110, the distance between the gate electrode 50 and a first mesa 25a (on the source electrode 30 side) of a cap layer 25 is defined as Lrs and the distance between the gate electrode 50 and a second mesa 25b (on the drain electrode 40 side) of the cap layer 25 is defined as Lrd.

With the semiconductor device 110 also referred to as a practical example, it is assumed that the position of a gate edge 52 on the drain electrode 40 side is 0, that the source electrode 30 side from the gate edge 52 on the drain electrode 40 side is negative, and that the drain electrode 40 side from the gate edge 52 on the drain electrode 40 side is positive. With the semiconductor device 110 also referred to as a practical example, the distance Le from the gate edge 52 on the drain electrode 40 side to an edge 60b of an insulating film 60 (insulating film edge) is set to −10 nm. With the semiconductor device 120 also referred to as a comparative example, a surface 20a of a semiconductor layer 20 as a whole is covered with an insulating film 60 and a gate electrode 50 is formed over the insulating film 60.

In the semiconductor device 110 also referred to as a practical example, sheet resistance between the gate electrode 50 and the source electrode 30 is 203 Ω/□ and sheet resistance between the gate electrode 50 and the drain electrode 40 is 259 Ω/□. On the other hand, in the semiconductor device 120 also referred to as a comparative example, sheet resistance between the gate electrode 50 and a source electrode 30 is 203 Ω/□ and sheet resistance between the gate electrode 50 and a drain electrode 40 is 203 Ω/□.

The above semiconductor devices 110 and 120 are used for evaluating the current-voltage characteristics.

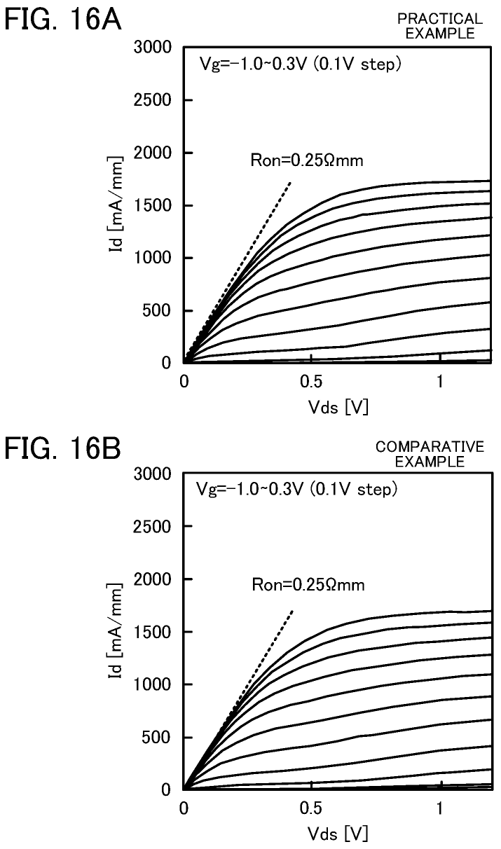

FIGS. 16A through 19B are views for describing the current-voltage characteristic of a semiconductor device.

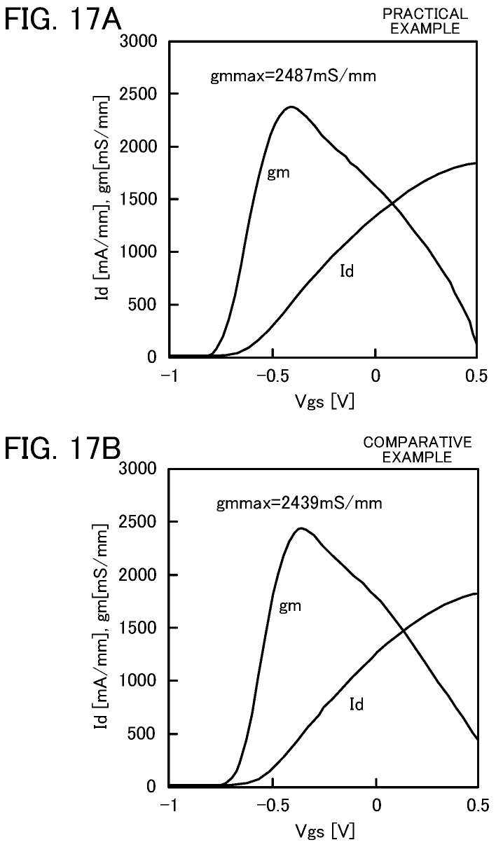

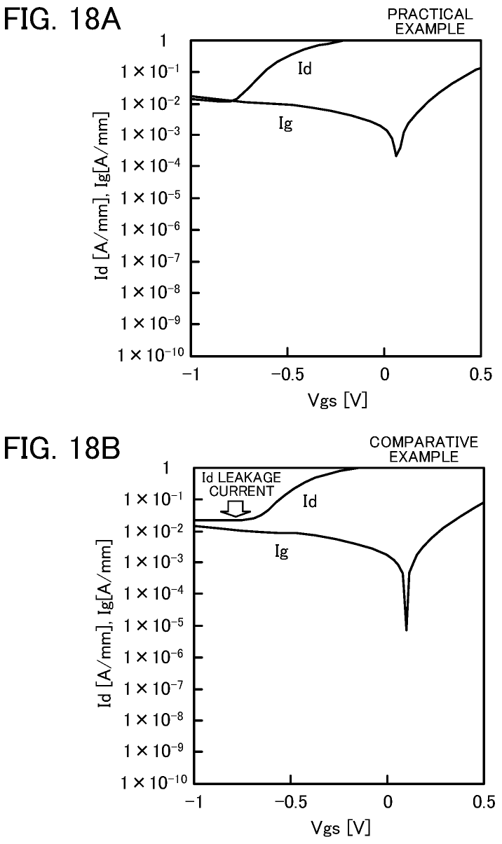

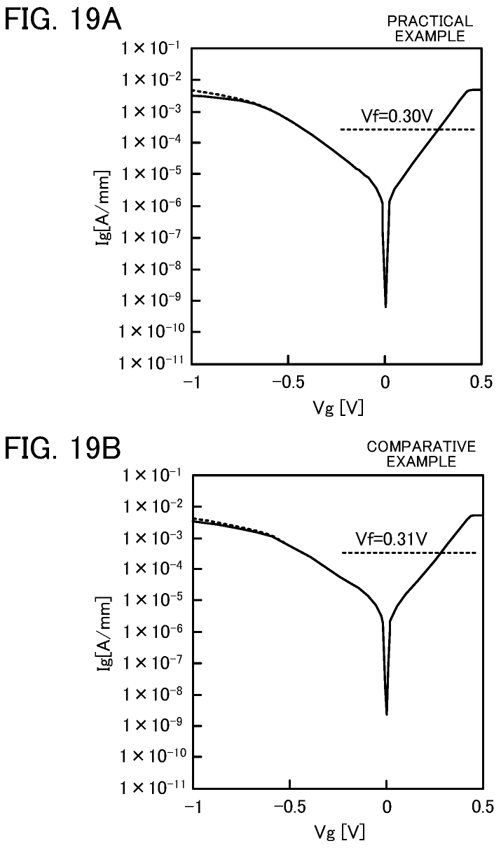

FIGS. 16A and 16B illustrate the relationship between a drain-source voltage Vds (V) and a drain current Id (mA/mm) for the semiconductor device 110 also referred to as a practical example and the semiconductor device 120 also referred to as a comparative example, respectively. FIGS. 17A and 17B illustrate the relationship between a gate-source voltage Vgs (V) and the drain current Id (mA/mm) and mutual conductance gm (mS/mm) for the semiconductor device 110 also referred to as a practical example and the semiconductor device 120 also referred to as a comparative example, respectively. FIGS. 18A and 18B illustrate the relationship between the gate-source voltage Vgs (V) and the drain current Id (mA/mm) and a gate current Ig (A/mm) for the semiconductor device 110 also referred to as a practical example and the semiconductor device 120 also referred to as a comparative example, respectively. FIGS. 19A and 19B illustrate the relationship between a gate voltage Vg (V) and the gate current Ig (A/mm) for the semiconductor device 110 also referred to as a practical example and the semiconductor device 120 also referred to as a comparative example, respectively.

From FIGS. 16A and 16B, there is no great difference in the relationship between the drain-source voltage Vds and the drain current Id between the semiconductor device 110 also referred to as a practical example and the semiconductor device 120 also referred to as a comparative example. On-state resistance Ron is estimated at 0.25 Ωmm for both of the semiconductor device 110 also referred to as a practical example and the semiconductor device 120 also referred to as a comparative example.

From FIGS. 17A and 17B, there is no great difference in the relationship between the gate-source voltage Vgs and the drain current Id and the mutual conductance gm between the semiconductor device 110 also referred to as a practical example and the semiconductor device 120 also referred to as a comparative example. The maximum value gmmax of the mutual conductance gm is estimated at 2487 mS/mm for the semiconductor device 110 also referred to as a practical example. The maximum value gmmax of the mutual conductance gm is estimated at 2439 mS/mm for the semiconductor device 120 also referred to as a comparative example.

From FIG. 18A, a flow of the drain current Id is stopped in an off state of the semiconductor device 110 also referred to as a practical example. On the other hand, from FIG. 18B, the drain current Id flows in an off state of the semiconductor device 120 also referred to as a comparative example. That is to say, it is recognized that a drain leakage current is generated.

From FIGS. 19A and 19B, there is no great difference in the relationship between the gate voltage Vg and the gate current Ig between the semiconductor device 110 (flat band voltage Vf=0.30 V) also referred to as a practical example and the semiconductor device 120 (Vf=0.31 V) also referred to as a comparative example.

From these results of the current-voltage characteristics, the following is ascertained. With the semiconductor device 110 also referred to as a practical example, it is possible to suppress generation of a drain leakage current while virtually maintaining the drain current Id and the mutual conductance gm, compared with the semiconductor device 120 also referred to as a comparative example.

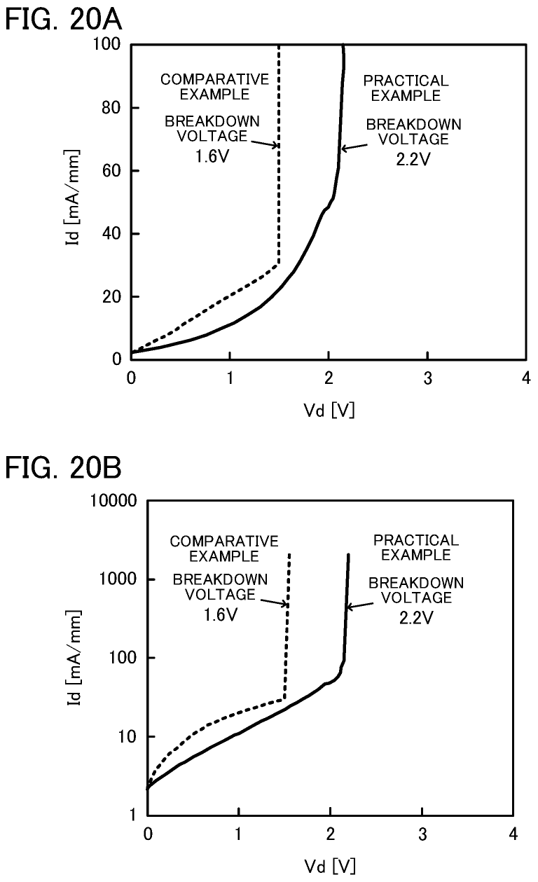

FIGS. 20A and 20B are views for describing the breakdown voltage of a semiconductor device.

FIG. 20A illustrates the relationship between a drain voltage Vd (V) and the drain current Id (mA/mm) on a linear scale for the semiconductor device 110 also referred to as a practical example and the semiconductor device 120 also referred to as a comparative example. FIG. 20B illustrates the relationship between the drain voltage Vd (V) and the drain current Id (mA/mm) on a logarithmic scale for the semiconductor device 110 also referred to as a practical example and the semiconductor device 120 also referred to as a comparative example.

From FIGS. 20A and 20B, the breakdown voltage of the semiconductor device 120 also referred to as a comparative example is 1.6 V. On the other hand, from FIGS. 20A and 20B, the breakdown voltage of the semiconductor device 110 also referred to as a practical example is 2.2 V. It is ascertained that the breakdown voltage of the semiconductor device 110 also referred to as a practical example is substantially improved compared with that of the semiconductor device 120 also referred to as a comparative example.

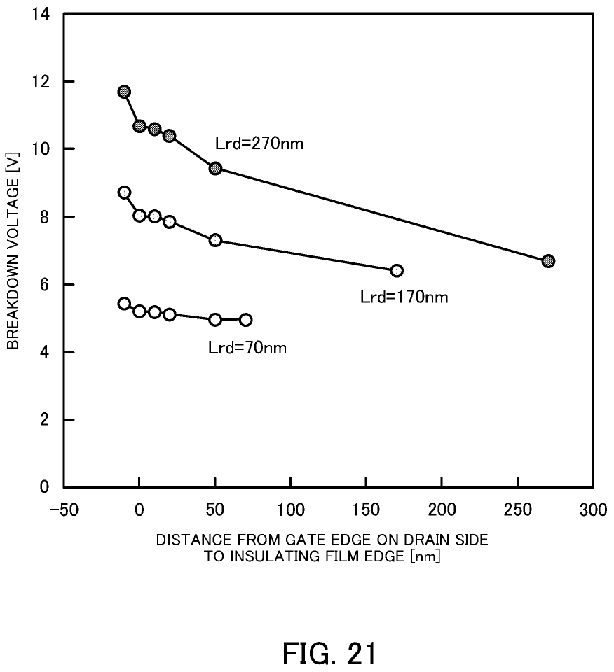

FIG. 21 is a view for describing the relationship between the distance from a gate edge on a drain side to an insulating film edge in a semiconductor device and the breakdown voltage of the semiconductor device.

FIG. 21 illustrates simulation results of the breakdown voltage (V) of the semiconductor device 110 (FIG. 15A) also referred to as a practical example obtained in the case of the distance Lrd (nm) between the gate electrode 50 and the second mesa 25b of the cap layer 25 and the distance Le (nm) from the gate edge 52 on the drain electrode 40 side to the edge 60b of the insulating film 60 being changed. The position of the gate edge 52 on the drain electrode 40 side corresponds to 0 nm on the horizontal axis of FIG. 21, the source electrode 30 side from the gate edge 52 on the drain electrode 40 side is negative on the horizontal axis of FIG. 21, and the drain electrode 40 side from the gate edge 52 on the drain electrode 40 side is positive on the horizontal axis of FIG. 21.

From FIG. 21, it is ascertained that as the distance Lrd between the gate electrode 50 and the second mesa 25b increases from 70 nm, to 170 nm, and to 270 nm, the breakdown voltage rises. The reason for this is that as the distance Lrd increases, an area of a channel layer 22 covered with the second mesa 25b, that is to say, an area in which a 2DEG 80 is densely generated narrows on the drain electrode 40 side from the gate electrode 50. In other words, as the distance Lrd increases, an area directly under an area between the gate electrode 50 and the drain electrode 40 in which the density of the 2DEG 80 is relatively low widens.

From FIG. 21, the following tendency is recognized in a case where the distance Lrd is set to 70 nm, a case where the distance Lrd is set to 170 nm, and a case where the distance Lrd is set to 270 nm. That is to say, it is assumed that the edge 60b of the insulating film 60 is situated at the gate edge 52 on the drain electrode 40 side (0 nm). As the edge 60b of the insulating film 60 extends from the gate edge 52 on the drain electrode 40 side to the drain electrode 40 side, it is recognized that the breakdown voltage tends to drop. The reason for this is that as the edge 60b of the insulating film 60 extends to the drain electrode 40 side, an area in which the density of the 2DEG 80 increases due to positive charges in the insulating film 60 widens.

Furthermore, from FIG. 21, the following tendency is recognized in the case where the distance Lrd is set to 70 nm, the case where the distance Lrd is set to 170 nm, and the case where the distance Lrd is set to 270 nm. That is to say, it is assumed that the edge 60b of the insulating film 60 is situated at the gate edge 52 on the drain electrode 40 side (0 nm). When the edge 60b of the insulating film 60 is situated on the source electrode 30 side from the gate edge 52 on the drain electrode 40 side, it is recognized that the breakdown voltage tends to rise. The reason for this is that the insulating film 60 does not exist at the gate edge 52 on the drain electrode 40 side at which electric field concentration relatively tends to occur and that an increase in the density of the 2DEG 80 directly under the gate edge 52 on the drain electrode 40 side is suppressed.

In addition, from FIG. 21, the following may be said. That is to say, the tendency of the breakdown voltage to increase (slope from the 0 nm side to the negative side) realized if the edge 60b of the insulating film 60 is situated on the source electrode 30 side from the gate edge 52 on the drain electrode 40 side is stronger than the tendency of the breakdown voltage to increase (slope from the positive side to the 0 nm side) realized if the edge 60b of the insulating film 60 is brought near the gate edge 52 on the drain electrode 40 side from the drain electrode 40 side. It may safely be said from this that to position the edge 60b of the insulating film 60 on the source electrode 30 side from the gate edge 52 on the drain electrode 40 side is more effective in improving the breakdown voltage than to bring the edge 60b of the insulating film 60 near the gate edge 52 on the drain electrode 40 side from the drain electrode 40 side.

### Fourth Embodiment

Still another configuration example of a semiconductor device will now be described as a fourth embodiment.

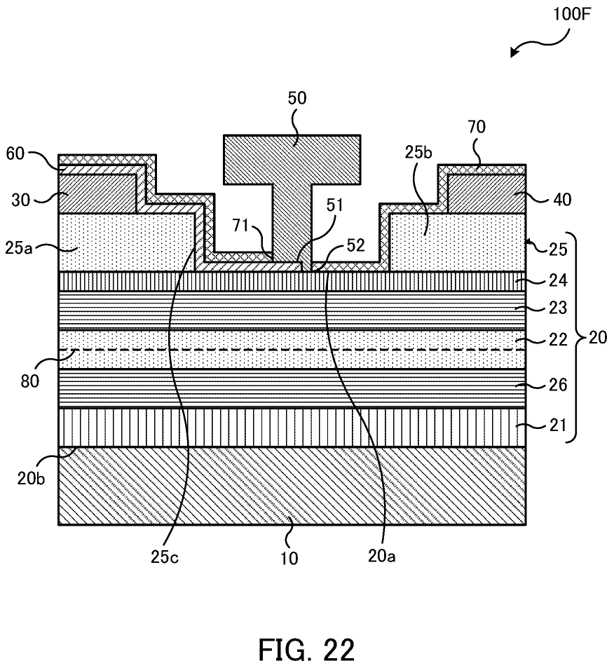

FIG. 22 is a view for describing a semiconductor device according to a first configuration example of a fourth embodiment. FIG. 22 is a fragmentary schematic sectional view of an example of a semiconductor device.

A semiconductor device 100F illustrated in FIG. 22 is an example of a HEMT. The semiconductor device 100F includes a semiconductor layer 20 also including an electron supply layer 26 formed between a buffer layer 21 and a channel layer 22. With the semiconductor device 100F, the channel layer 22 is formed between the electron supply layer 26 on the lower layer side and an electron supply layer 23 on the upper layer side of the semiconductor layer 20.

For example, the electron supply layer 26 is formed by the use of InAlAs. For example, the thickness of the electron supply layer 26 is set in the range of about 2 to 25 nm. For example, a determined area of the electron supply layer 26 is doped with impurities, such as Si, at determined concentration. The buffer layer 21, the electron supply layer 26, the channel layer 22, the electron supply layer 23, an etching stop layer 24, and a cap layer 25 are laminated in order over a substrate 10 by the use of the MOCVD method or the like. By doing so, the semiconductor layer 20 including the electron supply layer 26 is formed. A 2DEG 80 is generated in the channel layer 22 formed between the electron supply layer 26 and the electron supply layer 23.

The electron supply layer 26 over the buffer layer 21 is formed by introducing impurities by delta doping (atomic layer doping) or the like. Doping is performed by the use of impurities, such as Si, at a concentration of about 2×10¹² cm⁻². An interface between the buffer layer 21 and the electron supply layer 26 is doped with the impurities in sheet form. The interface doped with the impurities has a depth of about 3 to 5 nm from the surface of the electron supply layer 26. In this case, a portion of the electron supply layer 26 on the surface side from the interface doped with the impurities may be considered as a spacer layer.

The semiconductor layer 20 including the electron supply layer 26 illustrated in FIG. 22 may be used as a semiconductor layer 20 over a substrate 10. With the semiconductor device 100F in which the semiconductor layer 20 including the electron supply layer 26 is used, a high output and a high breakdown voltage are also realized by forming the insulating film 60 described in the above second embodiment.

With the semiconductor device 100F, an asymmetrical arrangement may be adopted. That is to say, a gate electrode 50 may be located nearer to a first mesa 25a on the source electrode 30 side than to a second mesa 25b on the drain electrode 40 side.

The semiconductor layer 20 including the electron supply layer 26 illustrated in FIG. 22 may be adopted in any of the semiconductor devices 100, 100A, 100B, 100C, 100D, 100E, and the like described in the above second embodiment.

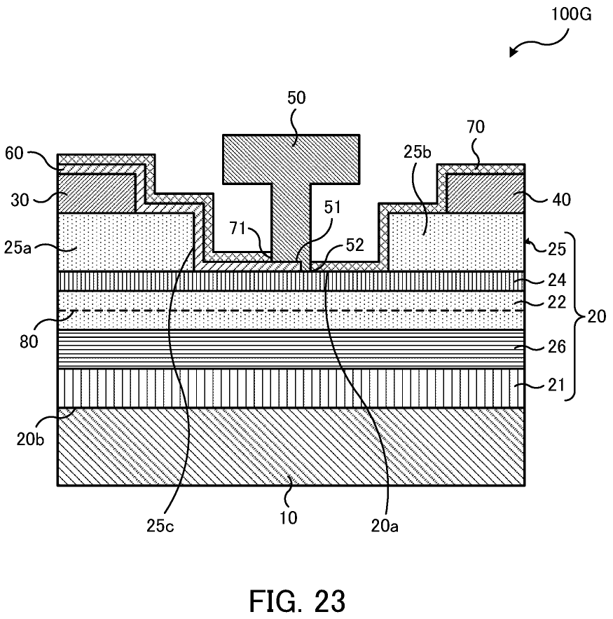

FIG. 23 is a view for describing a semiconductor device according to a second configuration example of the fourth embodiment. FIG. 23 is a fragmentary schematic sectional view of an example of a semiconductor device.

A semiconductor device 100G illustrated in FIG. 23 is an example of a HEMT. The semiconductor device 100G includes over a substrate 10 a semiconductor layer 20 in which a buffer layer 21, an electron supply layer 26, a channel layer 22, an etching stop layer 24, and a cap layer 25 are laminated in order. A 2DEG 80 is generated in the channel layer 22 over the electron supply layer 26. Each layer is laminated in order by the use of the MOCVD method or the like. By doing so, the semiconductor layer 20 illustrated in FIG. 23 is formed.

The semiconductor layer including the electron supply layer 26 under the channel layer 22 and not including an electron supply layer 23 over the channel layer 22 may be used as a semiconductor layer 20 over a substrate 10. With the semiconductor device 100G in which this semiconductor layer 20 is used, a high output and a high breakdown voltage are also realized by forming the insulating film 60 described in the above second embodiment.

With the semiconductor device 100G, an asymmetrical arrangement may be adopted. That is to say, a gate electrode 50 may be located nearer to a first mesa 25a on the source electrode 30 side than to a second mesa 25b on the drain electrode 40 side.

The semiconductor layer 20 having a laminated structure illustrated in FIG. 23 may be adopted in any of the semiconductor devices 100, 100A, 100B, 100C, 100D, 100E, and the like described in the above second embodiment.

The first through fourth embodiments have been described.

The above semiconductor devices 1, 1A, 1B, 1C (also described as “1 and 1A through 1C”), and the like and the above semiconductor devices 100, 100A, 100B, 100C, 100D, 100E, 100F, 100G (also described as “100 and 100A through 100G”), and the like may be applied to various electronic devices. For example, cases where the semiconductor devices having the above structures are applied to a semiconductor package, a power factor correction circuit, a power supply device, and an amplifier will now be described.

### Fifth Embodiment

An example of the application of the semiconductor devices having the above structures to a semiconductor package will now be described as a fifth embodiment.

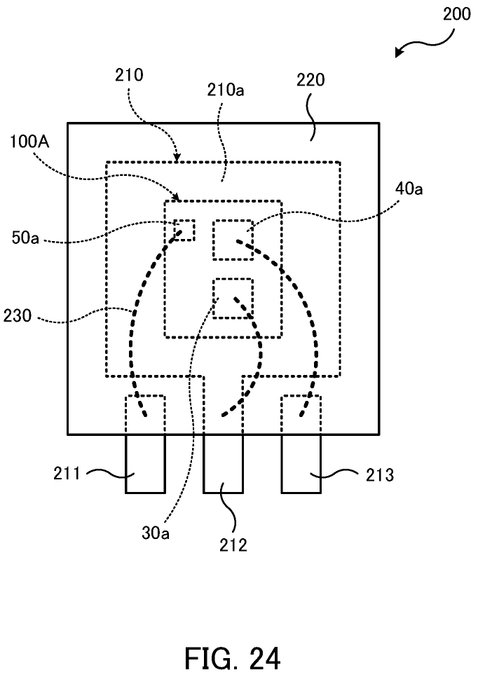

FIG. 24 is a view for describing an example of a semiconductor package according to a fifth embodiment. FIG. 24 is a fragmentary schematic plan view of an example of a semiconductor package.

A semiconductor package 200 illustrated in FIG. 24 is an example of a discrete package. For example, the semiconductor package 200 includes the semiconductor device 100A (FIG. 7) described in the above second embodiment, a lead frame 210 over which the semiconductor device 100A is mounted, and resin 220 which seals them.

For example, the semiconductor device 100A is mounted over a die pad 210a of the lead frame 210 by the use of a die attaching agent or the like (not illustrated). A pad 50a connected to the above gate electrode 50, a pad 30a connected to the source electrode 30, and a pad 40a connected to the drain electrode 40 are formed on the semiconductor device 100A. The pad 50a, the pad 30a, and the pad 40a are connected to a gate lead 211, a source lead 212, and a drain lead 213, respectively, of the lead frame 210 by the use of wires 230 made of Au, Al, or the like. The lead frame 210, the semiconductor device 100A mounted over the lead frame 210, and the wires 230 which connect the lead frame 210 and the semiconductor device 100A are sealed with the resin 220 such that part of each of the gate lead 211, the source lead 212, and the drain lead 213 is exposed.

An external connection electrode connected to the source electrode 30 may be formed on a surface of the semiconductor device 100A opposite to a surface over which the pad 50a connected to the gate electrode 50 and the pad 40a connected to the drain electrode 40 are formed. The external connection electrode may be connected to the die pad 210a which connects with the source lead 212 by the use of a conductive bonding material such as solder.

For example, the semiconductor device 100A described in the above second embodiment is used and the semiconductor package 200 having the above structure is obtained.

As stated above, with the semiconductor device 100A, the insulating film 60 containing AlₓO_{y} (y/x<3/2) having oxygen vacancies is formed on the surface 20a side of the semiconductor layer 20 on which the gate electrode 50, the source electrode 30, and the drain electrode 40 are formed and on the source electrode 30 side from the gate electrode 50. As a result, the density of the 2DEG 80 in the channel layer 22 on the source electrode 30 side from the gate electrode 50 is relatively higher than the density of the 2DEG 80 in the channel layer 22 on the drain electrode 40 side from the gate electrode 50. Accordingly, the density of the 2DEG 80 on the source electrode 30 side is increased, an electric field on the drain electrode 40 side is suppressed, and a high output and high breakdown voltage semiconductor device 100A is realized. This semiconductor device 100A is used and a high performance semiconductor package 200 is realized.

The semiconductor device 100A has been taken as an example. However, the other semiconductor devices 1, 1A through 1C, and the like and semiconductor devices 100, 100B through 100G, and the like may also be used for obtaining a semiconductor package.

### Sixth Embodiment

An example of the application of the semiconductor devices having the above structures to a power factor correction circuit will now be described as a sixth embodiment.

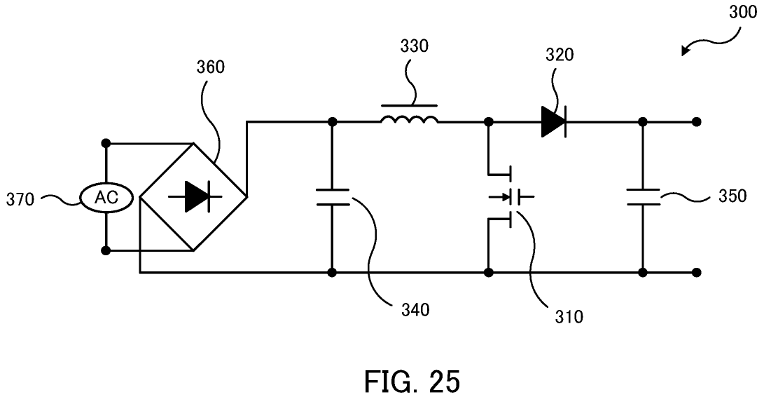

FIG. 25 is a view for describing an example of a power factor correction circuit according to a sixth embodiment. FIG. 25 is an equivalent circuit diagram of an example of a power factor correction circuit.

A power factor correction (PFC) circuit 300 illustrated in FIG. 25 includes a switching element 310, a diode 320, a choke coil 330, a condenser 340, a condenser 350, a diode bridge 360, and an alternating-current power supply 370 (AC).

In the PFC circuit 300, a drain electrode of the switching element 310, an anode terminal of the diode 320, and one terminal of the choke coil 330 are connected. A source electrode of the switching element 310, one terminal of the condenser 340, and one terminal of the condenser 350 are connected. The other terminal of the condenser 340 and the other terminal of the choke coil 330 are connected. The other terminal of the condenser 350 and a cathode terminal of the diode 320 are connected. Furthermore, a gate driver is connected to a gate electrode of the switching element 310. The alternating-current power supply 370 is connected via the diode bridge 360 between both terminals of the condenser 340 and a direct-current power supply (DC) is taken from between both terminals of the condenser 350.

For example, the above semiconductor devices 1, 1A through 1C, and the like and semiconductor devices 100, 100A through 100G, and the like are used as the switching element 310 included in the PFC circuit 300 having the above structure.

As stated above, with the semiconductor devices 1, 1A through 1C, and the like and the semiconductor devices 100, 100A through 100G, and the like, the insulating film 60 containing AlₓO_{y} (y/x<3/2) having oxygen vacancies is formed on the surface 20a side of the semiconductor layer 20 on which the gate electrode 50, the source electrode 30, and the drain electrode 40 are formed and on the source electrode 30 side from the gate electrode 50. As a result, the density of the 2DEG 80 in the channel layer 22 on the source electrode 30 side from the gate electrode 50 is relatively higher than the density of the 2DEG 80 in the channel layer 22 on the drain electrode 40 side from the gate electrode 50. Accordingly, the density of the 2DEG 80 on the source electrode 30 side is increased, an electric field on the drain electrode 40 side is suppressed, and high output and high breakdown voltage semiconductor devices 1, 1A through 1C, and the like and semiconductor devices 100, 100A through 100G, and the like are realized. These semiconductor devices 1, 1A through 1C, and the like and semiconductor devices 100, 100A through 100G, and the like are used and a high performance PFC circuit 300 is realized.

### Seventh Embodiment

An example of the application of the semiconductor devices having the above structures to a power supply device will now be described as a seventh embodiment.

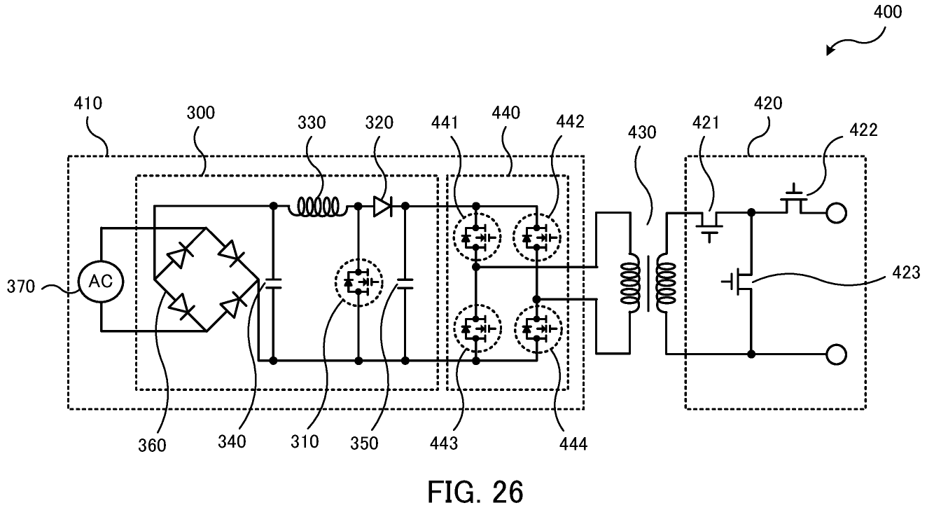

FIG. 26 is a view for describing an example of a power supply device according to a seventh embodiment. FIG. 26 is an equivalent circuit diagram of an example of a power supply device.

A power supply device 400 illustrated in FIG. 26 includes a primary-side circuit 410, a secondary-side circuit 420, and a transformer 430 located between the primary-side circuit 410 and the secondary-side circuit 420.

The primary-side circuit 410 includes the PFC circuit 300 described in the above sixth embodiment and an inverter circuit, such as a full-bridge inverter circuit 440 connected between both terminals of the condenser 350 of the PFC circuit 300. The full-bridge inverter circuit 440 includes a plurality of switching elements. In this example, the full-bridge inverter circuit 440 includes four switching elements 441, 442, 443, and 444.

The secondary-side circuit 420 includes a plurality of switching elements. In this example, the secondary-side circuit 420 includes three switching elements 421, 422, and 423.

For example, the above semiconductor devices 1, 1A through 1C, and the like and semiconductor devices 100, 100A through 100G, and the like are used as the switching element 310 of the PFC circuit 300 and the switching elements 441 through 444 of the full-bridge inverter circuit 440 included in the primary-side circuit 410 of the power supply device 400 having the above structure. For example, ordinary MIS-type field-effect transistors made of Si are used as the switching elements 421 through 423 of the secondary-side circuit 420 of the power supply device 400.

As stated above, with the semiconductor devices 1, 1A through 1C, and the like and the semiconductor devices 100, 100A through 100G, and the like, the insulating film 60 containing AlₓO_{y} (y/x<3/2) having oxygen vacancies is formed on the surface 20a side of the semiconductor layer 20 on which the gate electrode 50, the source electrode 30, and the drain electrode 40 are formed and on the source electrode 30 side from the gate electrode 50. As a result, the density of the 2DEG 80 in the channel layer 22 on the source electrode 30 side from the gate electrode 50 is relatively higher than the density of the 2DEG 80 in the channel layer 22 on the drain electrode 40 side from the gate electrode 50. Accordingly, the density of the 2DEG 80 on the source electrode 30 side is increased, an electric field on the drain electrode 40 side is suppressed, and high output and high breakdown voltage semiconductor devices 1, 1A through 1C, and the like and semiconductor devices 100, 100A through 100G, and the like are realized. These semiconductor devices 1, 1A through 1C, and the like and semiconductor devices 100, 100A through 100G, and the like are used and a high performance power supply device 400 is realized.

### Eighth Embodiment

An example of the application of the semiconductor devices having the above structures to an amplifier will now be described as an eighth embodiment.

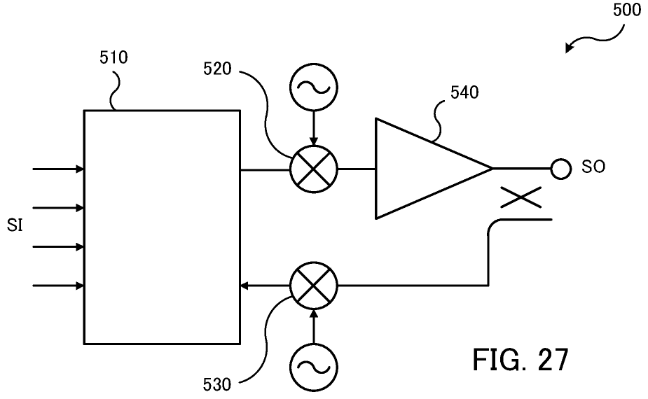

FIG. 27 is a view for describing an example of an amplifier according to an eighth embodiment. FIG. 27 is an equivalent circuit diagram of an example of an amplifier.

An amplifier 500 illustrated in FIG. 27 includes a digital predistortion circuit 510, a mixer 520, a mixer 530, and a power amplifier 540.

The digital predistortion circuit 510 compensates for nonlinear distortion of an input signal. The mixer 520 mixes an input signal SI whose nonlinear distortion has been compensated for with an alternating-current signal. The power amplifier 540 amplifies the input signal SI mixed with the alternating-current signal. With the amplifier 500, an output signal SO is mixed with an alternating-current signal by the mixer 530 and is transmitted to the digital predistortion circuit 510, for example, by switching a switch. The amplifier 500 may be used as a high-frequency amplifier or a high output amplifier.

The above semiconductor devices 1, 1A through 1C, and the like and semiconductor devices 100, 100A through 100G, and the like are used as the power amplifier 540 of the amplifier 500 having the above structure.

As stated above, with the semiconductor devices 1, 1A through 1C, and the like and the semiconductor devices 100, 100A through 100G, and the like, the insulating film 60 containing AlₓO_{y} (y/x<3/2) having oxygen vacancies is formed on the surface 20a side of the semiconductor layer 20 on which the gate electrode 50, the source electrode 30, and the drain electrode 40 are formed and on the source electrode 30 side from the gate electrode 50. As a result, the density of the 2DEG 80 in the channel layer 22 on the source electrode 30 side from the gate electrode 50 is relatively higher than the density of the 2DEG 80 in the channel layer 22 on the drain electrode 40 side from the gate electrode 50. Accordingly, the density of the 2DEG 80 on the source electrode 30 side is increased, an electric field on the drain electrode 40 side is suppressed, and high output and high breakdown voltage semiconductor devices 1, 1A through 1C, and the like and semiconductor devices 100, 100A through 100G, and the like are realized. These semiconductor devices 1, 1A through 1C, and the like and semiconductor devices 100, 100A through 100G, and the like are used and a high performance amplifier 500 is realized.

Various electronic devices (such as the semiconductor package 200, the PFC circuit 300, the power supply device 400, and the amplifier 500 described in the above fifth through eighth embodiments, respectively) to which the above semiconductor devices 1, 1A through 1C, and the like and semiconductor devices 100, 100A through 100G, and the like are applied may be mounted in various electronic apparatus or devices such as computers (personal computers, supercomputers, servers, and the like), smartphones, portable telephones, tablet terminals, sensors, cameras, audio equipment, measuring equipment, inspection equipment, manufacturing equipment, transmitters, receivers, and radar systems.

According to an aspect, a high output and high breakdown voltage semiconductor device is realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a semiconductor layer including a first layer containing indium, gallium, and arsenic and a second layer laminated over the first layer and containing indium, aluminum, and arsenic;
a source electrode and a drain electrode provided on a first surface side of the semiconductor layer where a first surface of the semiconductor layer is located;
a gate electrode provided on the first surface side of the semiconductor layer between the source electrode and the drain electrode; and
a first insulating film provided on the first surface side of the semiconductor layer and on a source electrode side, where the source electrode is provided, from the gate electrode, the first insulating film containing aluminum oxide having oxygen vacancies.

2. The semiconductor device according to claim 1 further comprising a second insulating film which connects with the first insulating film, which is provided between the first surface of the semiconductor layer and an end surface of the gate electrode that faces the first surface, and which contains aluminum oxide.

3. The semiconductor device according to claim 2, wherein an edge of the second insulating film closest to the drain electrode is situated closer to the source electrode than an edge of the end surface of the gate electrode closest to the drain electrode.

4. The semiconductor device according to claim 2, wherein an edge of the second insulating film closest to the drain electrode is situated at an edge of the end surface of the gate electrode closest to the drain electrode.

5. The semiconductor device according to claim 2, wherein a composition ratio of oxygen to aluminum in aluminum oxide contained in the second insulating film is higher than a composition ratio of oxygen to aluminum in aluminum oxide contained in the first insulating film.

6. The semiconductor device according to claim 2, wherein a side of the second insulating film closest to the drain electrode is inclined such that a thickness of the second insulating film decreases toward the drain electrode.

7. The semiconductor device according to claim 2, wherein a thickness of the second insulating film is less than a thickness of the first insulating film.

8. The semiconductor device according to claim 2 further comprising a third insulating film which connects with the second insulating film, which is provided on a drain electrode side, where the drain electrode is provided, from the gate electrode, and which contains aluminum oxide.

9. The semiconductor device according to claim 1 further comprising a fourth insulating film which is provided on the first surface side of the semiconductor layer, which covers the first insulating film provided on the source electrode side from the gate electrode and a drain electrode side, where the drain electrode is provided, from the gate electrode, and which contains silicon nitride.

10. The semiconductor device according to claim 1, wherein:
the semiconductor layer further includes, on the first surface side, a third layer including a recess and a first mesa and a second mesa opposite each other with the recess therebetween;
the source electrode and the drain electrode are provided over the first mesa and the second mesa, respectively; and
the gate electrode is provided apart from the first mesa and the second mesa in the recess.

11. The semiconductor device according to claim 10, wherein the first insulating film covers an area in the recess between the gate electrode and the first mesa.

12. The semiconductor device according to claim 10, wherein the semiconductor layer further includes a fourth layer provided under a bottom of the recess.

13. The semiconductor device according to claim 1 further comprising a substrate located on a second surface side of the semiconductor layer opposite to the first surface side, the substrate containing indium and phosphorus.

14. The semiconductor device according to claim 1, wherein the second layer, of the first layer and the second layer of the semiconductor layer, is provided on the first surface side.

15. A semiconductor device manufacturing method comprising:
forming a semiconductor layer including a first layer containing indium, gallium, and arsenic and a second layer laminated over the first layer and containing indium, aluminum, and arsenic;
forming a source electrode and a drain electrode on a first surface side of the semiconductor layer where a first surface of the semiconductor layer is located;
forming a gate electrode on the first surface side of the semiconductor layer between the source electrode and the drain electrode; and
forming a first insulating film containing aluminum oxide having oxygen vacancies on the first surface side of the semiconductor layer and on a source electrode side, where the source electrode is formed, from the gate electrode.

16. The semiconductor device manufacturing method according to claim 15 further comprising forming a second insulating film which connects with the first insulating film, between the first surface of the semiconductor layer and an end surface of the gate electrode that faces the first surface, the second insulating film containing aluminum oxide.

17. The semiconductor device manufacturing method according to claim 16, wherein the forming of the second insulating film includes oxidizing aluminum oxide contained in the second insulating film.

18. The semiconductor device manufacturing method according to claim 16 further comprising forming a third insulating film which connects with the second insulating film, on a drain electrode side, where the drain electrode is provided, from the gate electrode, the third insulating film containing aluminum oxide.

19. An electronic device comprising a semiconductor device including:
a semiconductor layer having a first layer containing indium, gallium, and arsenic and a second layer laminated over the first layer and containing indium, aluminum, and arsenic;
a source electrode and a drain electrode provided on a first surface side of the semiconductor layer where a first surface of the semiconductor layer is located;
a gate electrode provided on the first surface side of the semiconductor layer between the source electrode and the drain electrode; and
a first insulating film provided on the first surface side of the semiconductor layer and on a source electrode side, where the source electrode is provided, from the gate electrode, the first insulating film containing aluminum oxide having oxygen vacancies.
